(19) United States
(12) Patent Application Publication
(10) Pub. No.: US 2024/0172468 A1
(43) Pub. Date: May 23, 2024

(54) LIGHT-EMITTING DEVICE MANUFACTURING METHOD AND LIGHT-EMITTING DEVICE

(71) Applicant: SHARP KABUSHIKI KAISHA, Sakai City, Osaka (JP)

(72) Inventors: Takahiro ADACHI, Sakai City, Osaka (JP); YASUSHI ASAOKA, Sakai City, Osaka (JP)

(21) Appl. No.: 18/272,601

(22) PCT Filed: Jan. 20, 2021
(86) PCT No.: PCT/JP2021/001796

§ 371 Date: Jul. 17, 2023

(51) Int. Cl. H10K 50/16; C09K 11/06; H10K 50/11; H10K 50/15; H10K 71/20; H10K 85/60

(52) U.S. Cl. CPC H10K 50/16; C09K 11/06; H10K 50/11; H10K 50/15; H10K 71/20; H10K 85/626

(57) ABSTRACT

A method of manufacturing a light-emitting device according to the disclosure includes, in a light-emitting element formation step of forming, on a substrate, a first light-emitting element including a first light-emitting layer, a first light-emitting layer formation step of forming the first light-emitting layer by forming a layered body obtained by layering, in order from the substrate side, a lower reversal resist layer, a light-emitting material layer containing a light-emitting material of the first light-emitting layer, and an upper layer positive resist, and patterning the layered body.

### TECHNICAL FIELD

The disclosure relates to a light-emitting device provided with a plurality of light-emitting elements, and to a method of manufacturing the light-emitting device.

### BACKGROUND ART

PTL 1 discloses a technique of mixing quantum dots into a photoresist, and patterning a layer containing the quantum dots using photolithography.

### CITATION LIST

### Patent Literature

PTL 1: US 2017/0176854 A1

### SUMMARY

### Technical Problem

With the technique disclosed in PTL 1, a layer containing quantum dots of each color is formed on the entire surface and patterned by photolithography, and this process is repeated. Therefore, quantum dots may remain as a residue at a position where the layer containing the quantum dots was removed. Accordingly, a problem of color mixing occurs.

### Solution to Problem

To solve the abovementioned problem, a method of manufacturing a light-emitting device of the disclosure includes a light-emitting element formation step in which a first light-emitting element including a first light-emitting layer is formed on a substrate, wherein the light-emitting element formation step includes a first light-emitting layer formation step of forming the first light-emitting layer by patterning a first layered body obtained by layering, in order from the substrate side, a first reversal resist, a first light-emitting material layer containing a light-emitting material of the first light-emitting layer, and a first positive resist.

To solve the abovementioned problem, a light-emitting device of the disclosure includes a substrate, and a first light-emitting element on the substrate, the first light-emitting element including a first lower layer electrode, a first light-emitting layer, and a first upper layer electrode layered in this order from the substrate side, wherein the first light-emitting element further includes a photosensitive resin layer between the first lower layer electrode and the first light-emitting layer, and the photosensitive resin layer includes at least one selected from the group consisting of compounds represented by the following structural formulas (1) to (3), and at least one selected from the group consisting of aromatic hydrocarbons having a hydroxyl group, 1-hydroxyethyl-2-alkylimidazoline, and shellac.

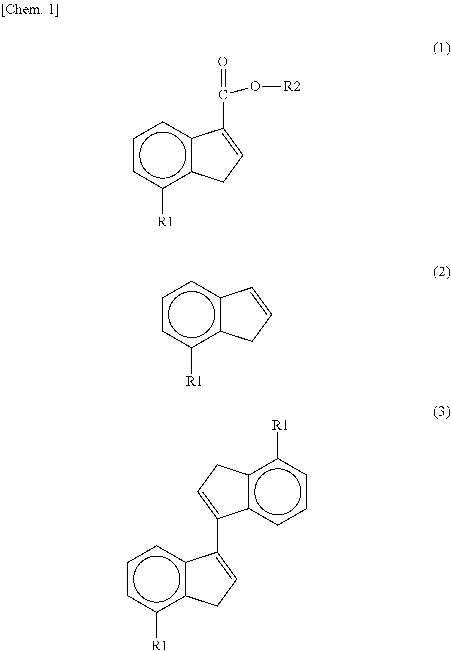

Here, R1 and R2 each independently represent a substituted or unsubstituted hydrocarbon group.

### Advantageous Effects of Disclosure

According to one aspect of the disclosure, mixing of the light-emitting material of the first light-emitting layer as a residue into a region where the first light-emitting layer is not formed is reduced.

### BRIEF DESCRIPTION OF DRAWINGS

FIG. 1 is a flowchart describing an example of a method of manufacturing a display device according to the disclosure.

FIG. 2 is a schematic plan view illustrating an example of a configuration of a display device according to the disclosure.

FIG. 3 is a schematic cross-sectional view illustrating an example of a configuration of a display region of a display device according to the disclosure.

FIG. 4 is a schematic cross-sectional view illustrating an example of a configuration of a light-emitting element layer in a display device according to one embodiment of the disclosure.

FIG. 5 is a schematic flowchart describing an example of a step for forming, on a substrate, the example of the light-emitting element layer illustrated in FIG. 4.

FIG. 6 is a schematic flowchart describing a process executed in a step of carrying out a process including the formation of a red light-emitting layer and a step of carrying out a process including the formation of a green light-emitting layer 35g, the steps thereof being described in FIG. 5.

FIG. 7 is a schematic flowchart describing a process executed in a step described in FIG. 5 of carrying out a process including the formation of a blue light-emitting layer.

FIG. 8 is a schematic cross-sectional view illustrating an example of steps of forming, on a substrate, the example of the light-emitting element layer illustrated in FIG. 4.

FIG. 9 is a schematic cross-sectional view illustrating an example of steps of forming, on a substrate, the example of the light-emitting element layer illustrated in FIG. 4.

FIG. 10 is a schematic cross-sectional view illustrating an example of steps of forming, on a substrate, the example of the light-emitting element layer illustrated in FIG. 4.

FIG. 11 is a schematic cross-sectional view illustrating an example of steps of forming, on a substrate, the example of the light-emitting element layer illustrated in FIG. 4.

FIG. 12 is a schematic cross-sectional view illustrating an example of steps of forming, on a substrate, the example of the light-emitting element layer illustrated in FIG. 4.

FIG. 13 is a schematic cross-sectional view illustrating an example of steps of forming, on a substrate, the example of the light-emitting element layer illustrated in FIG. 4.

FIG. 14 is a schematic cross-sectional view illustrating an example of steps of forming, on a substrate, the example of the light-emitting element layer illustrated in FIG. 4.

FIG. 15 is a schematic cross-sectional view illustrating an example of steps of forming, on a substrate, the example of the light-emitting element layer illustrated in FIG. 4.

FIG. 16 is a schematic cross-sectional view illustrating an example of steps of forming, on a substrate, the example of the light-emitting element layer illustrated in FIG. 4.

FIG. 17 is a schematic cross-sectional view illustrating an example of steps of forming, on a substrate, the example of the light-emitting element layer illustrated in FIG. 4.

FIG. 18 is a schematic cross-sectional view illustrating an example of steps of forming, on a substrate, the example of the light-emitting element layer illustrated in FIG. 4.

FIG. 19 is a schematic cross-sectional view illustrating an example of steps of forming, on a substrate, the example of the light-emitting element layer illustrated in FIG. 4.

FIG. 20 is a schematic cross-sectional view illustrating another example of a configuration of a light-emitting element layer in a display device according to one embodiment of the disclosure.

FIG. 21 is a schematic cross-sectional view illustrating another example of a step of forming, on a substrate, the example of the light-emitting element layer illustrated in FIG. 4.

FIG. 22 is a schematic cross-sectional view illustrating another example of steps of forming, on a substrate, the example of the light-emitting element layer illustrated in FIG. 4.

FIG. 23 is a schematic cross-sectional view illustrating another example of steps of forming, on a substrate, the example of the light-emitting element layer illustrated in FIG. 4.

FIG. 24 is a schematic cross-sectional view illustrating another example of steps of forming, on a substrate, the example of the light-emitting element layer illustrated in FIG. 4.

FIG. 25 is a schematic cross-sectional view illustrating another example of steps of forming, on a substrate, the example of the light-emitting element layer illustrated in FIG. 4.

FIG. 26 is a schematic cross-sectional view illustrating another example of a configuration of a light-emitting element layer in a display device according to one embodiment of the disclosure.

FIG. 27 is a schematic flowchart describing an example of a step of forming, on a substrate, the example of the light-emitting element layer illustrated in FIG. 26.

FIG. 28 is a schematic cross-sectional view illustrating another example of a configuration of the light-emitting element layer in a display device according to an embodiment of the disclosure.

FIG. 29 is a schematic energy level diagram illustrating an example of band gaps of a hole transport layer, a lower resin layer, a light-emitting layer, and an electron transport layer of the light-emitting element layer illustrated in FIG. 4.

FIG. 30 is a schematic energy level diagram illustrating an example of band gaps of a hole transport layer, a lower resin layer, a light-emitting layer, and an electron transport layer of the light-emitting element layer illustrated in FIG. 20.

FIG. 31 is a schematic energy level diagram illustrating an example of band gaps of a hole transport layer, a lower resin layer, a light-emitting layer, and an electron transport layer of the light-emitting element layer illustrated in FIG. 20.

FIG. 32 is a schematic energy level diagram illustrating an example of band gaps of a hole transport layer, a lower resin layer, a light-emitting layer, and an electron transport layer of the light-emitting element layer illustrated in FIG. 26.

FIG. 33 is a schematic energy level diagram illustrating an example of band gaps of a hole transport layer, a lower resin layer, a light-emitting layer, and an electron transport layer of the light-emitting element layer illustrated in FIG. 28.

FIG. 34 is a schematic energy level diagram illustrating an example of band gaps of a hole transport layer, a lower resin layer, a light-emitting layer, and an electron transport layer of the light-emitting element layer illustrated in FIG. 28.

FIG. 35 is a schematic cross-sectional view illustrating an example of a configuration of a light-emitting element layer in a display device according to another embodiment of the disclosure.

FIG. 36 is a schematic cross-sectional view illustrating an example of steps of forming, on a substrate, the example of the light-emitting element layer illustrated in FIG. 35.

FIG. 37 is a schematic cross-sectional view illustrating an example of steps of forming, on a substrate, the example of the light-emitting element layer illustrated in FIG. 35.

FIG. 38 is a schematic cross-sectional view illustrating an example of steps of forming, on a substrate, the example of the light-emitting element layer illustrated in FIG. 35.

FIG. 39 is a schematic cross-sectional view illustrating an example of steps of forming, on a substrate, the example of the light-emitting element layer illustrated in FIG. 35.

FIG. 40 is a schematic cross-sectional view illustrating an example of steps of forming, on a substrate, the example of the light-emitting element layer illustrated in FIG. 35.

FIG. 41 is a schematic cross-sectional view illustrating an example of a configuration of a light-emitting element layer in a display device according to yet another embodiment of the disclosure.

FIG. 42 is a schematic flowchart describing a process that is executed to form the light-emitting element layer illustrated in FIG. 41.

FIG. 43 is a schematic cross-sectional view illustrating the process illustrated in FIG. 42.

FIG. 44 is a schematic cross-sectional view illustrating the process illustrated in FIG. 42 and a process illustrated in FIG. 45 described below.

FIG. 45 is a schematic flowchart describing another process that is executed to form the light-emitting element layer illustrated in FIG. 41.

FIG. 46 is a schematic cross-sectional view illustrating the process described in FIG. 45.

FIG. 47 is a schematic cross-sectional view illustrating an example of a configuration of a light-emitting element layer in a display device according to yet another embodiment of the disclosure.

FIG. 48 is a schematic flowchart describing an example of a step of forming, on a substrate, the example of the light-emitting element layer illustrated in FIG. 47.

FIG. 49 is a schematic flowchart describing an example of steps of forming, on a substrate, the example of the light-emitting element layer illustrated in FIG. 47.

FIG. 50 is a schematic flowchart describing an example of steps of forming, on a substrate, the example of the light-emitting element layer illustrated in FIG. 47.

FIG. 51 is a schematic cross-sectional view illustrating an example of steps of forming, on a substrate, the example of the light-emitting element layer illustrated in FIG. 47.

FIG. 52 is a schematic cross-sectional view illustrating an example of steps of forming, on a substrate, the example of the light-emitting element layer illustrated in FIG. 47.

FIG. 53 is a schematic cross-sectional view illustrating an example of steps of forming, on a substrate, the example of the light-emitting element layer illustrated in FIG. 47.

### DESCRIPTION OF EMBODIMENTS

### First Embodiment

### Method of Manufacturing Display Device and Configuration

In the following description, the “same layer” means a layer formed through the same process (film formation step), the “lower layer” means that a layer formed through a process before that of the layer to be compared, and the “upper layer” means that a layer formed through a process after that of the layer to be compared.

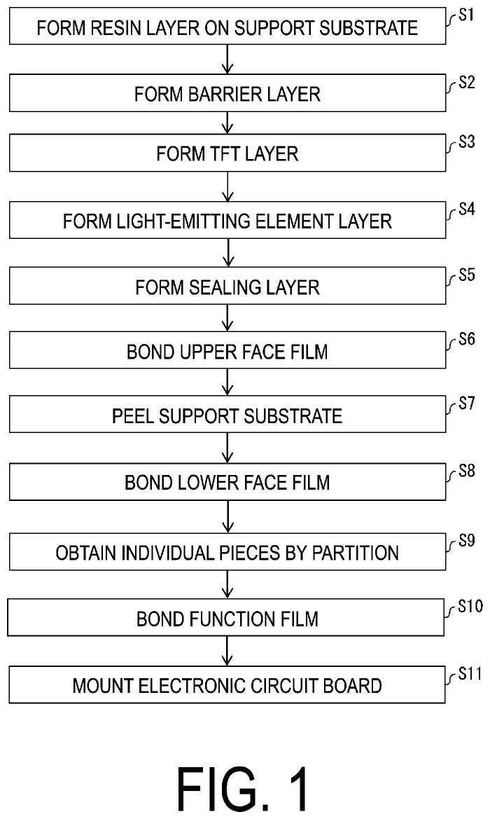

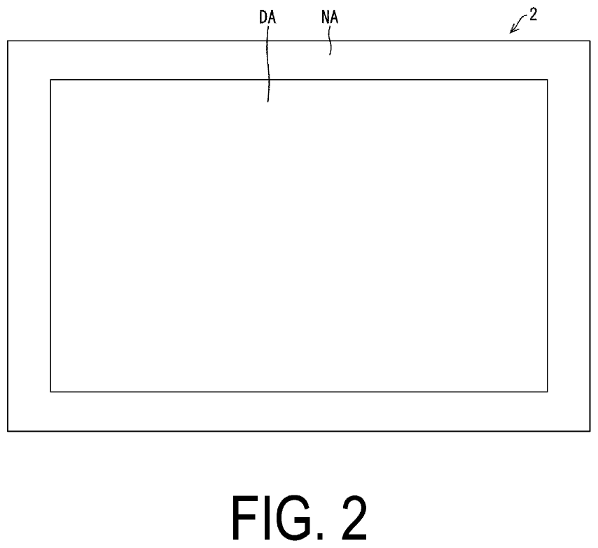

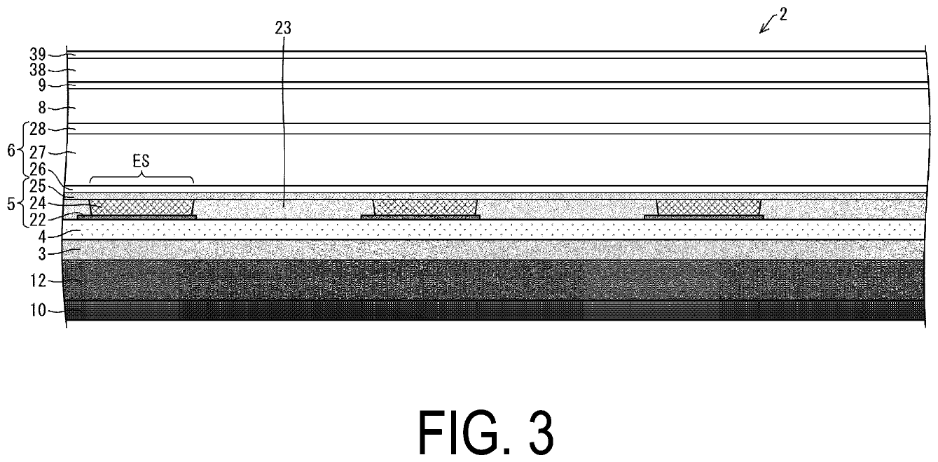

FIG. 1 is a flowchart illustrating an example of a method for manufacturing a display device. FIG. 2 is a plan view illustrating an example of a configuration of a display device 2 (light-emitting device). FIG. 3 is a schematic cross-sectional view illustrating an example of a configuration of a display region DA of the display device 2 illustrated in FIG. 2.

When a flexible display device 2 is to be manufactured, as illustrated in FIGS. 1 to 3, a resin layer 12 is first formed on a light-transmissive support substrate 13 (for example, mother glass) (step S1). Next, a barrier layer 3 is formed (step S2). Next, a thin film transistor layer (TFT layer) 4 is formed (step S3). Next, a top-emitting type light-emitting element layer 5 is formed (step S4). Next, a sealing layer 6 is formed (step S5). Next, an upper face film 9 is bonded to the sealing layer 6 via an adhesive layer 8 therebetween (step S6).

Next, the support substrate is peeled from the resin layer 12 through irradiation with laser light or the like (step S7). Next, a lower face film 10 is bonded to the lower face of the resin layer 12 (step S8). Next, a layered body including the lower face film 10, the resin layer 12, the barrier layer 3, the thin film transistor layer 4, the light-emitting element layer 5, and the sealing layer 6 is divided to obtain a plurality of individual pieces (step S9). Next, a function film 39 is bonded to the obtained individual pieces through an adhesive layer 38 (step S10). Next, an electronic circuit board (for example, an IC chip and a flexible printed circuit (FPC)) is mounted on a portion (terminal portion) of a frame region NA (non-display region) surrounding a display region DA where a plurality of subpixels are formed (step S11). Note that steps S1 to S11 are executed by a display device manufacturing apparatus (including a film formation apparatus that executes the process from steps S1 to S5).

The light-emitting element layer 5 includes an anode 22 (anode electrode, so-called pixel electrode) of a more upper layer than a flattening film 21, an edge cover 23 having insulating properties and covering an edge of the anode 22, an active layer 24, which is an electroluminescent (EL) layer of a more upper layer than the edge cover 23, and a cathode 25 (cathode electrode, so-called common electrode) of a more upper layer than the active layer 24.

For each subpixel, a light-emitting element ES (electroluminescent element) including the anode 22 having an island shape, the active layer 24, and the cathode 25 and being a QLED is formed in the light-emitting element layer 5, and a subpixel circuit for controlling the light-emitting element ES is formed in the thin film transistor layer 4.

The sealing layer 6 is light-transmissive, and includes an inorganic sealing film 26 for covering the cathode 25, an organic buffer film 27 which is an upper layer above the inorganic sealing film 26, and an inorganic sealing film 28 which is an upper layer above the organic buffer film 27. The sealing layer 6 covering the light-emitting element layer 5 inhibits foreign matters such as water and oxygen from penetrating the light-emitting element layer 5.

The flexible display device has been described above, but when manufacturing the display device as a non-flexible display device, because typical formation of the resin layer and replacement of the substrate are not required, the process proceeds to step S9 after the layering process on the glass substrate of steps S2 to S5 is executed. Furthermore, when a non-flexible display device is manufactured, a light-transmissive sealing member may be caused to adhere using a sealing adhesive instead of or in addition to forming the sealing layer 6, under a nitrogen atmosphere. The light-transmissive sealing member can be formed from glass, plastic, or the like, and preferably has a concave shape.

A first embodiment particularly relates to a step of forming the light-emitting element layer 5 (step S4) of the method of manufacturing a display device described above. The first embodiment relates particularly to the active layer 24 of the configuration of the display device described above.

### Configuration of Light-Emitting Element Layer

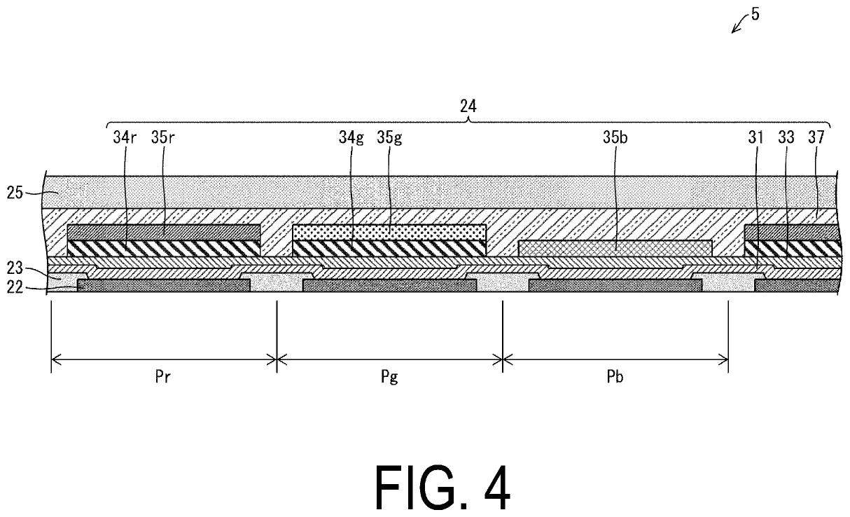

FIG. 4 is a schematic cross-sectional view illustrating an example of a configuration of the light-emitting element layer 5 in the display device 2 according to the first embodiment.

In an example of the light-emitting element layer 5 illustrated in FIG. 4, a red subpixel Pr (first light-emitting element, red light-emitting element), a green subpixel Pg (second light-emitting element, green light-emitting element), and a blue subpixel Pb (third light-emitting element, blue light-emitting element) are formed on a substrate (that is, the lower face film 10 or a mother glass 70 described later). Hereinafter, the red subpixel Pr, the green subpixel Pg, and the blue subpixel Pb are collectively referred to as “subpixels P”.

An example of the light-emitting element layer 5 illustrated in FIG. 4 includes, in the region of the red subpixel Pr, the anode 22 (lower layer electrode, first lower layer electrode), a hole injection layer 31, a hole transport layer 33 (carrier transport layer), a red lower resin layer 34r (photosensitive resin layer), a red light-emitting layer 35r (first light-emitting layer), an electron transport layer 37, and the cathode 25 (upper layer electrode, first upper layer electrode), in this order from the substrate side (lower side in FIG. 4).

Similarly, an example of the light-emitting element layer 5 includes, in the region of the green subpixel Pg, the anode 22 (second lower layer electrode), the hole injection layer 31, the hole transport layer 33, a green lower resin layer 34g (photosensitive resin layer), a green light-emitting layer 35g (second light-emitting layer), the electron transport layer 37, and the cathode 25 (second upper layer electrode), in this order from the substrate side.

Similarly, an example of the light-emitting element layer 5 includes, in the region of the blue subpixel Pb, the anode 22 (third lower layer electrode), the hole injection layer 31, the hole transport layer 33, a blue light-emitting layer 35b (third light-emitting layer), the electron transport layer 37, and the cathode 25 (third upper layer electrode), in this order from the substrate side.

Hereinafter, the red lower resin layer 34r and the green lower resin layer 34g are collectively referred to as a “lower resin layer 34”. In addition, the red light-emitting layer 35r, the green light-emitting layer 35g, and the blue light-emitting layer 35b are collectively referred to as a “light-emitting layer 35”.

The hole injection layer 31 may be omitted.

The hole transport layer 33 includes a hole transport material. Examples of the hole transport material include inorganic materials such as NiO, CuI, Cu₂O, CoO, Cr₂O₃, and CuAlS. Other examples of the hole transport material include photo-curable organic materials such as PEDOT:PSS, poly((9,9-dioctylfluorenyl-2,7-diyl)-co(4,4′-(N-(4-sec-butylphenyl)diphenylamine)) (TFB), poly(N,N′-diphenyl-N,N′-di(m-tolyl)benzidine) (poly-TPD), (1,1-bis(-(N,N-di(p-tolyl) amino) phenyl) cyclohexane) (TAPC), organic polysilane compounds, N4,N4′-bis(4-(6-((3-ethyloxetan-3-yl)methoxy)hexyl)phenyl-N4,N4′-diphenylbiphenyl-4,4′diamine) (OTPD), N4,N4′-bis(4-(6-((3-ethyloxetan-3-yl)methoxy)hexyloxy)phenyl-N4,N4′-bis(-methoxyphenyl)biphenyl-4,4′-diamine) (QUPD), and N,N′-(4,4′-(cyclohexane-1,1-diyl)bis(4,4-phenylene))bis(N-(4-(6-(2-ethyloxetan-2-yloxy)hexyl)phenyl)-3,4,5-trifluoroaniline) (X-F6-TAPC).

The lower resin layer 34 is a resin layer formed from a reversal resist material. As used herein, “reversal resist material” means a material containing a reversal-type photoresist. In contrast, a “positive resist material” means a material containing a positive-type photoresist.

A positive resist contains, for example, an uncured resin and a sensitizer. The resin is soluble in the developing solution, and examples thereof include an acrylic resin, a novolac resin, a rubber resin, a styrene resin, and an epoxy resin. The sensitizer is, for example, a naphthoquinone diazide (NQD) compound. The NQD compound is insoluble in the developing solution. Further, the NQD compound is converted to an indene carboxylic acid compound by exposure to light as indicated in the following reaction formula (1). The indene carboxylic acid is soluble in a compound developing solution. The NQD compound is also referred to as a diazonaphthoquinone (DNQ) compound.

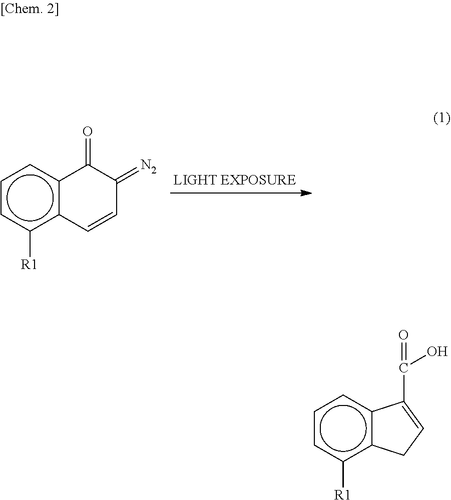

Here, R1 is a moiety other than the NQD group of the NQD compound and represents a substituted or unsubstituted hydrocarbon group.

The developing solution is an alkaline aqueous solution or an organic solvent. The alkaline aqueous solution is, for example, an aqueous solution of an inorganic material such as KOH and NaOH, or an aqueous solution of an organic material such as tetramethylammonium (TMAH). Examples of the organic solvent include propylene glycol monomethyl ether acetate (PGMEA), acetone, N-methyl-2-pyrrolidone (NMP), dimethyl sulfoxide (DMSO), and isopropanol (IPA).

Therefore, the positive resist is insoluble in the developing solution in an initial state before exposure to light, and becomes soluble in the developing solution by exposure to light.

The reversal resist is, for example, a positive resist to which a negative-working agent has been added. Examples of negative-working agents include amines, aromatic hydrocarbons having a hydroxyl group, 1-hydroxyethyl-2-alkylimidazoline, and shellacs. At the time of reversal firing, the negative working agent acts as a catalyst on the indene carboxylic acid compound to promote decarboxylation. Therefore, as indicated in the following reaction formulas (2) to (4), through heating, the indene carboxylic acid compound is converted to a compound that is insoluble in the developing solution. In particular, when the crosslinking reaction indicated in the reaction formula (2) is dominant, the reversal resist is cured.

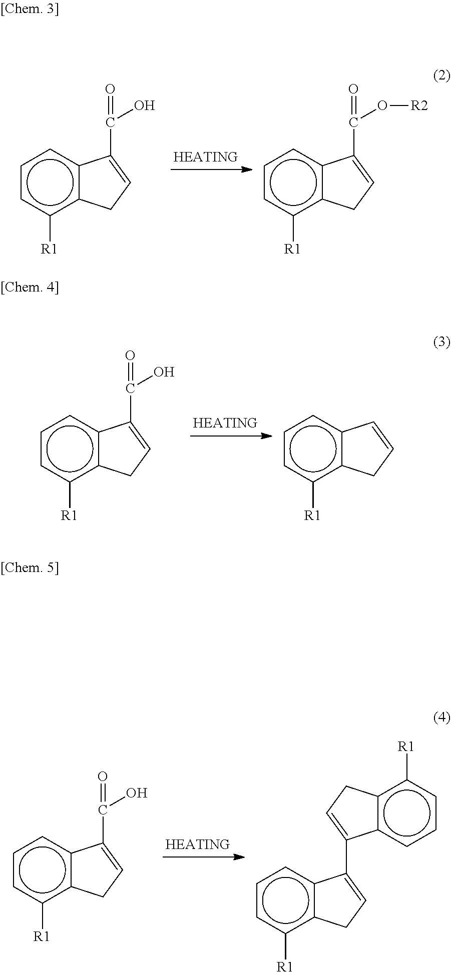

Here, R2 is a moiety other than the indene carboxyl group of the indene carboxylic acid compound or the resin contained in the reversal resist, and represents a substituted or unsubstituted hydrocarbon group.

Therefore, similar to the positive resist, the reversal resist is insoluble in the developing solution in an initial state before exposure to light, and becomes soluble in the developing solution by exposure to light. Further, the reversal resist is solubilized by exposure to light, and is then insolubilized once again in the developing solution by heating or laser irradiation. The term “re-insolubilized” herein means that the reversal resist is insolubilized once again in the developing solution after being solubilized therein. The re-insolubilized reversal resist is not solubilized when exposed to light once again.

The lower resin layer 34 is formed by re-insolubilizing the reversal resist as described above, or by re-insolubilizing the reversal resist and performing a main firing. Therefore, the lower resin layer 34 includes at least one selected from the group consisting of compounds represented by the following structural formulas (1) to (3), and at least one selected from the group consisting of aromatic hydrocarbons having a hydroxyl group, 1-hydroxyethyl-2-alkylimidazoline, and shellac.

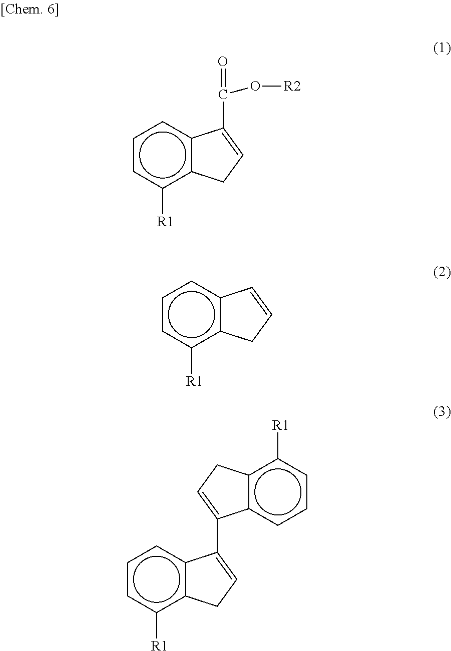

Here, R1 and R2 each independently represent a substituted or unsubstituted hydrocarbon group.

The thickness of the lower resin layer 34 is preferably 50 nm or less, and more preferably 40 nm or less. Since the resin is generally a dielectric and has high electrical resistivity, the thickness of the lower resin layer 34 contributes significantly to an increase or decrease in the electrical resistance of the entire light-emitting element. Therefore, the lower resin layer 34 is preferably thin in order to reduce the electrical resistance of the entire light-emitting element in a direction perpendicular to the substrate of the light-emitting layer 35.

The red lower resin layer 34r and the green lower resin layer 34g may be mutually integrated or separate from each other.

The light-emitting material included in each of the light-emitting layers 35 may be an organic light-emitting material or an inorganic light-emitting material such as quantum dots. The quantum dots may be core-shell type quantum dots or core-multishell type quantum dots. Examples of combinations of the core material and the shell material of the core-shell type quantum dots include CdSe/CdS, CdSe/ZnS, CdTe/CdS, INP/ZNS, GaP/ZNS, Si/ZNS, INN/GaN, INP/CdSSe, INP/ZNSeTe, GaINP/ZNSe, GaINP/ZNS, Si/AlP, INP/ZNSTe, GaINP/ZNSTe, and GaINP/ZNSSe. In the present specification, among the light-emitting materials, a light-emitting material contained in the red light-emitting layer 35r is referred to as a red light-emitting material. The red light-emitting material emits red light. Moreover, a light-emitting material contained in the green light-emitting layer 35g is referred to as a green light-emitting material. The green light-emitting material differs from the red light-emitting material and emits green light. Further, a light-emitting material contained in the blue light-emitting layer 35b is referred to as a blue light-emitting material. The blue light-emitting material emits blue light and is different from both the red light-emitting material and the green light-emitting material.

The light-emitting material contained in each of the light-emitting layers 35 is preferably quantum dots because of a below-described developing step. This is because when the light-emitting material is quantum dots, the developing solution can penetrate the light-emitting material layer and develop layers lower than the light-emitting material layer from the upper surface.

The electron transport layer 37 includes an electron transport material. Examples of the electron transport material include metal oxides such as ZnO, ZrO, MgZnO, AlZnO, and TiO₂, and metal sulfides such as ZnS.

### Manufacturing Method

Hereinafter, with reference to FIGS. 4 to 19, an example of a step (step S4, light-emitting element formation step) of forming, on a substrate, the example of the light-emitting element layer 5 illustrated in FIG. 4 will be described in detail.

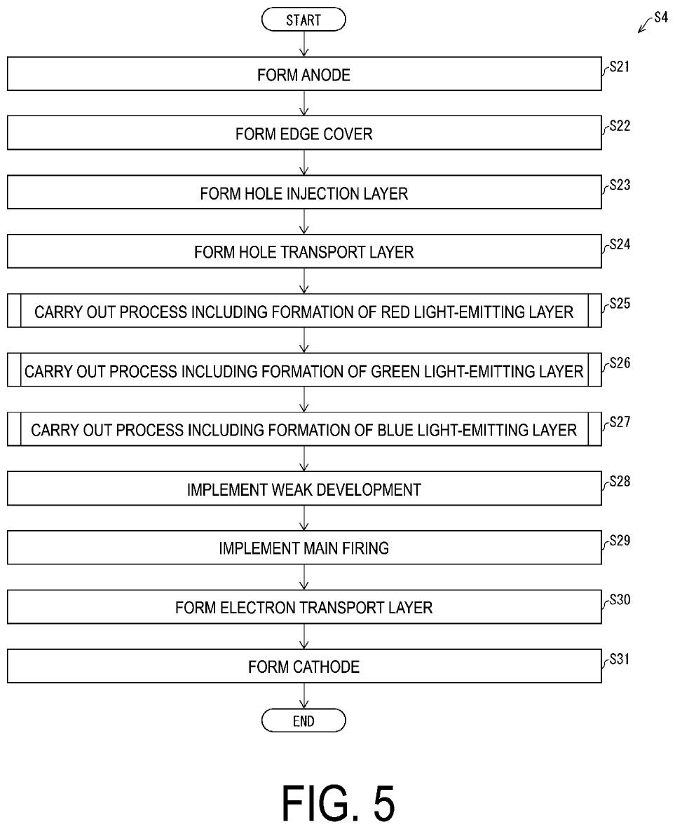

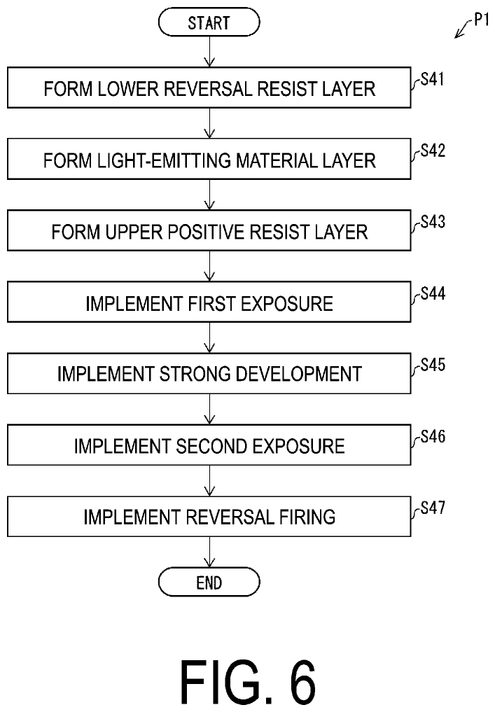

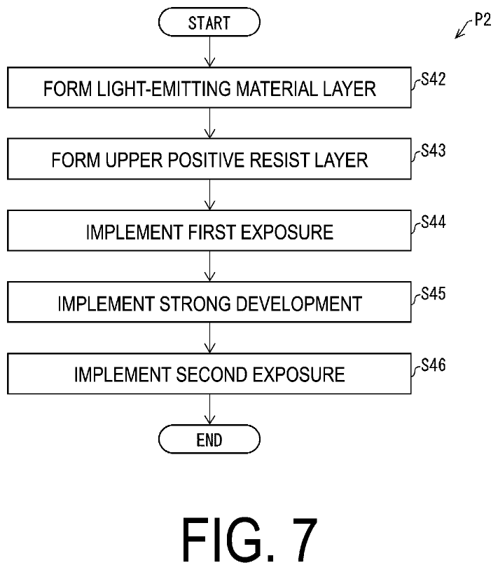

FIG. 5 is a schematic flowchart describing an example of a step (step S4) for forming, on a substrate, the example of the light-emitting element layer 5 illustrated in FIG. 4. FIG. 6 is a schematic flowchart describing a process (process P1) executed in the step (step S25) of carrying out a process including the formation of the red light-emitting layer 35r and the step (step S26) of carrying out a process including the formation of the green light-emitting layer 35g, the steps thereof being illustrated in FIG. 5. FIG. 7 is a schematic flowchart illustrating a process (process P2) executed in the step (step S27) described in FIG. 5 of carrying out a process including the formation of the blue light-emitting layer 35b.

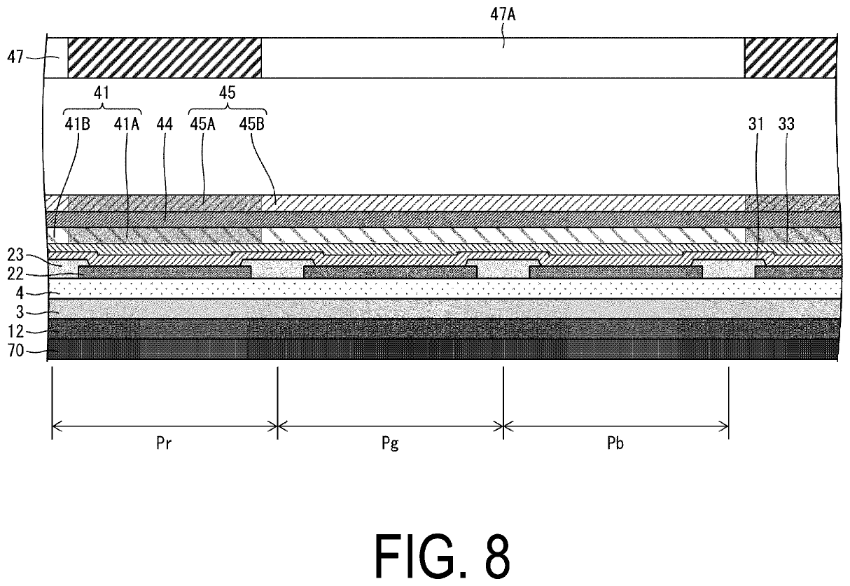

FIGS. 8 to 19 are each schematic cross-sectional views illustrating an example of a step (step S4) of forming, on a substrate, the example of the light-emitting element layer 5 illustrated in FIG. 4.

First, the above-described steps S1 to S3 (see FIG. 1) are carried out to prepare a substrate on which the resin layer 12, the barrier layer 3, and the thin film transistor layer 4 are formed in this order on the mother glass 70 (substrate).

Next, as illustrated in FIGS. 5 and 8, the anode 22 is formed in an island shape in each region of each subpixel P (step S21), the edge cover 23 is formed so as to cover the edge of the anode 22 (step S22), the hole injection layer 31 is formed on the entire surface (step S23), and the hole transport layer 33 is formed on the entire surface thereof (step S24). In the present specification, “on the entire surface” means that the target layer is commonly formed over the plurality of subpixels P without being patterned.

### Process Including Formation of Red Light-Emitting Layer

Next, as illustrated in FIG. 6 and FIGS. 8 to 11, a process that includes formation of the red light-emitting layer 35r is carried out (step S25). In this step, the red lower resin layer 34r is also formed before the main firing. In step S25, the process P1 described in FIG. 6 is executed.

That is, first, as illustrated in FIGS. 6 and 8, a red lower reversal resist layer 41 (first reversal resist) is formed (i.e., a film is formed) over the entire surface by applying a reversal resist material over the entire surface of the hole transport layer 33 (step S41, part of the layered body formation step among the first light-emitting layer formation step). Subsequently, a red light-emitting material layer 44 (first light-emitting material layer) is formed on the entire surface of red lower reversal resist layer 41 by vapor deposition of a material containing a red light-emitting material (light-emitting material of the first light-emitting layer) onto the entire surface thereof or by applying a solution containing a red light-emitting material onto the entire surface of the red lower reversal resist layer 41 and then volatilizing the solvent from the solution (step S42, part of the layered body formation step among the first light-emitting layer formation step). Subsequently, a positive resist material is applied to the entire surface of the red light-emitting material layer 44 to thereby form a red upper positive resist layer 45 (first positive resist) of a sufficient thickness on the entire surface as will be described later (step S43, part of the layered body formation step among the first light-emitting layer formation step).

In the present specification, unless otherwise specified, the method for applying the material of each member may be any method such as an ink-jet method, a spin coating method, or a bar coating method.

The resin material and sensitizer contained in the positive resist material in step S43 are preferably identical to the resin material and sensitizer contained in the reversal resist material in step S41. This is because the red lower reversal resist layer 41 and the red upper positive resist layer 45 can be patterned using photolithography under the same conditions, including the exposure wavelength and the developing solution.

In this manner, a layered body (first layered body) is formed including the red lower reversal resist layer 41, the red light-emitting material layer 44, and the red upper positive resist layer 45 in this order from the substrate side. At this time, the red lower reversal resist layer 41 and the red upper positive resist layer 45 are each insoluble in the developing solution.

Next, the layered body described above is subjected to a first exposure with ultraviolet light using a red first mask 47 (step S44, a layered body exposure step among the first light-emitting layer formation step). Because the red first mask 47 is used, a portion of the layered body is exposed, and the other portions are not exposed. An optical opening 47A is formed in the red first mask 47 such that a portion corresponding to the formation region of the red light-emitting layer 35r is light-blocking and the other portion is light-transmissive.

At this time, as indicated in the reaction formula (1), in the red lower reversal resist layer 41 and the red upper positive resist layer 45, the NQD compound insoluble in the developing solution is converted to an indene carboxylic acid compound that is soluble in the developing solution, the conversion occurring through a photochemical reaction when subjected to ultraviolet irradiation.

As a result, the portions of the red lower reversal resist layer 41 and the red upper positive resist layer 45 that do not correspond to the optical opening 47A (i.e., the portions that overlap the red light-emitting layer 35r) do not undergo the photochemical reaction, and thus remain as insoluble portions 41A and 45A that are insoluble in the developing solution. On the other hand, the other portions corresponding to the optical opening 47A are converted through the photochemical reaction to soluble portions 41B and 45B soluble in the developing solution.

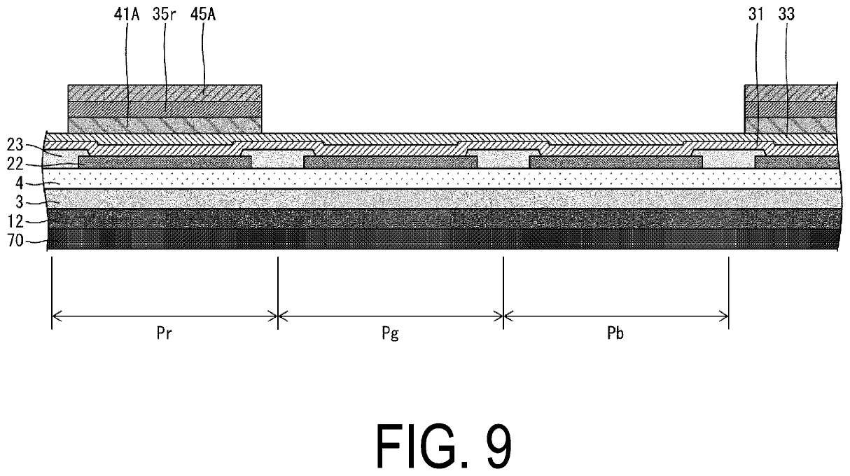

Next, as illustrated in FIGS. 6 and 9, development is carried out using a strong developing solution (step S45, developing step among the first light-emitting layer formation step). In the present specification, the term “strong developing solution” means an above-mentioned developing solution that (i) can dissolve the entire soluble portion of the resist layer above the light-emitting material layer (or light-emitting layer) by dissolving the soluble portion of the resist layer from the upper surface and the side surface, and (ii) can dissolve the entire soluble portion of the resist layer below the light-emitting material layer by dissolving, from the side surface, the soluble portion, and as a result, (iii) can release the portion of the light-emitting material layer in which the resist of the lower layer is the soluble portion. Further, as described above, when the light-emitting material is quantum dots, the developing solution can penetrate the light-emitting material layer and dissolve, from the upper surface and the side surface, the soluble portion of the resist layer below the light-emitting material layer.

The strong developing solution is, for example, a concentrated alkaline aqueous solution or an alkaline solution to which a surfactant is added at a high concentration. The pH of the concentrated alkaline aqueous solution is, for example, 12 or higher. The surfactant is, for example, a nonionic surfactant such as a fatty acid ester, a polyoxyethylene alkyl ether, a fatty acid polyethylene glycol, or a fatty acid alkanolamide, and the high concentration is, for example, 1 wt. % or higher. Nonionic surfactants are less susceptible to acids and alkalis. The surfactant promotes penetration into the light-emitting material layer. In the present specification, carrying out development using a strong developing solution is expressed as “carrying out strong development” or “strongly developing”.

As a result, the exposed portion of the layered body including the red light-emitting material layer 44 is removed by removing the soluble portion 41B (exposed first reversal resist) of the red lower reversal resist layer 41. On the other hand, the insoluble portion 41A of the red lower reversal resist layer 41 remains, and therefore an unexposed portion of the layered body remains. Accordingly, the soluble portions 41B and 45B of the red lower reversal resist layer 41 and the red upper positive resist layer 45 and the portion of the red light-emitting material layer 44 therebetween are removed. On the other hand, the insoluble portions 41A and 45A of the red lower reversal resist layer 41 and the red upper positive resist layer 45 and the portion of the red light-emitting material layer 44 therebetween remain. The remaining portion of the red light-emitting material layer 44 becomes the red light-emitting layer 35r.

By using the photolithography technique and re-insolubilization of the reversal resist in this manner, the layered body described above is patterned, and as a result, the red light-emitting layer 35r is formed. At the same time, the insoluble portions 41A and 45A of the red lower reversal resist layer 41 and the red upper positive resist layer 45 are formed so as to overlap the red light-emitting layer 35r in a plan view observed from a direction orthogonal to the substrate.

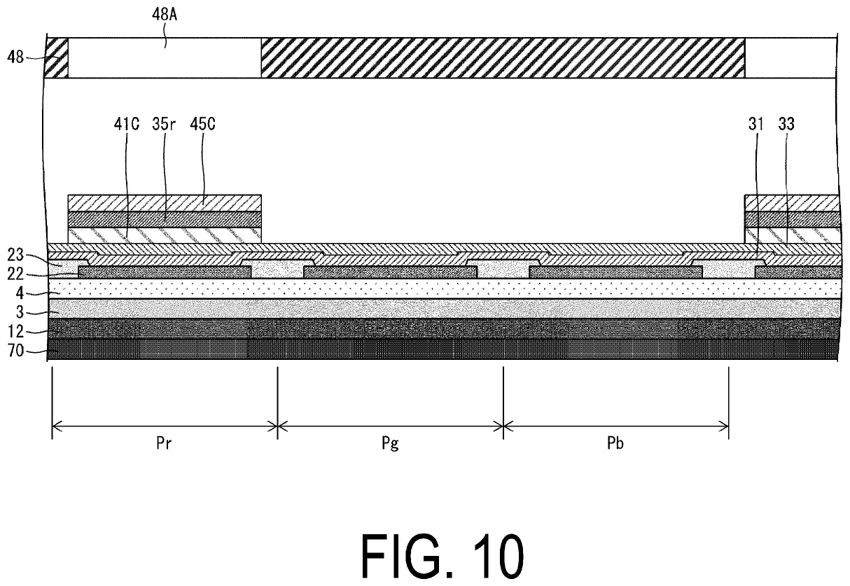

Next, as illustrated in FIGS. 6 and 10, the above-described layered body subjected to patterning is subjected to a second exposure with ultraviolet light using a red second mask 48 (step S46, a reversal resist exposure step among the first re-insolubilization step). An optical opening 48A is formed in the red second mask 48 such that a portion corresponding to the formation region of the red light-emitting layer 35r is light-transmissive and the other portion is light-blocking.

As a result, through a photochemical reaction, the insoluble portion 41A (the first reversal resist overlapping the first light-emitting layer) of the red lower reversal resist layer 41 and the insoluble portion 45A of the red upper positive resist layer 45 become a soluble portion 41C (the exposed first reversal resist) and a soluble portion 45C, respectively, the soluble portions 41C and 45C being soluble in the developing solution. Although the second exposure may be carried out without using a mask, use of the red second mask 48 is preferable from the viewpoint of reducing photodegradation.

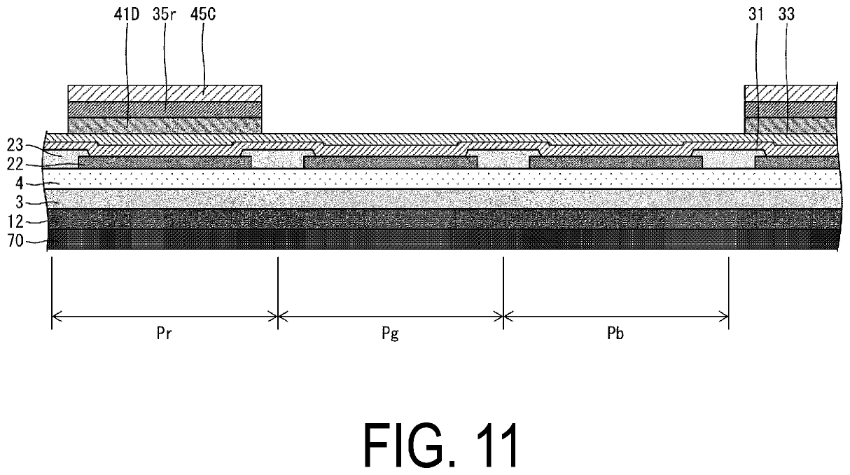

Next, as illustrated in FIGS. 6 and 11, the above-described layered body that was patterned is subjected to reversal firing (step S47, the heating step among the first re-insolubilization step). The reversal firing is heating or laser irradiation carried out such that the red lower reversal resist layer 41 is re-insolubilized without curing the red upper positive resist layer 45. Reversal firing is easily carried out by heating, and thus is preferable. The reversal firing carried out by heating is preferably implemented at a temperature lower than the temperature at which the positive resist constituting the red upper positive resist layer 45 is cured and for a length of time that is shorter than a time length at which the positive resist is cured. For example, if the red upper positive resist layer 45 is cured at a temperature of 120° C. or higher and for a time of 10 minutes or longer, the reversal firing is preferably implemented at a temperature less than 120° C. for a time of less than 10 minutes.

At this time, in the red lower reversal resist layer 41, the indene carboxylic acid compound that is soluble in the developing solution is converted by decarboxylation into a compound that is insoluble in the developing solution, as indicated in reaction formulas (2) to (4). On the other hand, in the red upper positive resist layer 45, the indene carboxylic acid compound that is soluble in the developing solution remains as the indene carboxylic acid compound.

As a result, through decarboxylation, the soluble portion 41C of the red lower reversal resist layer 41 becomes a re-insoluble portion 41D that is insoluble in the developing solution. The re-insoluble portion 41D of the red lower reversal resist layer 41 is used as is as the red lower resin layer 34r or becomes the red lower resin layer 34r after passing through a main firing (step S29) described later. On the other hand, the soluble portion 45C of the red upper positive resist layer 45 remains as the soluble portion 45C.

In step S25, as described above, the red light-emitting layer 35r is formed in a state of being sandwiched and protected between the re-insoluble portion 41D of the red lower reversal resist layer 41 and the soluble portion 45C of the red upper positive resist layer 45.

### Process Including Formation of Green Light-Emitting Layer

Next, as illustrated in FIG. 5 and FIGS. 12 to 15, a process that includes formation of the green light-emitting layer 35g is carried out (step S26). In this step, the green lower resin layer 34g is also formed before the main firing. The process P1 described in FIG. 6 is also executed in step S26.

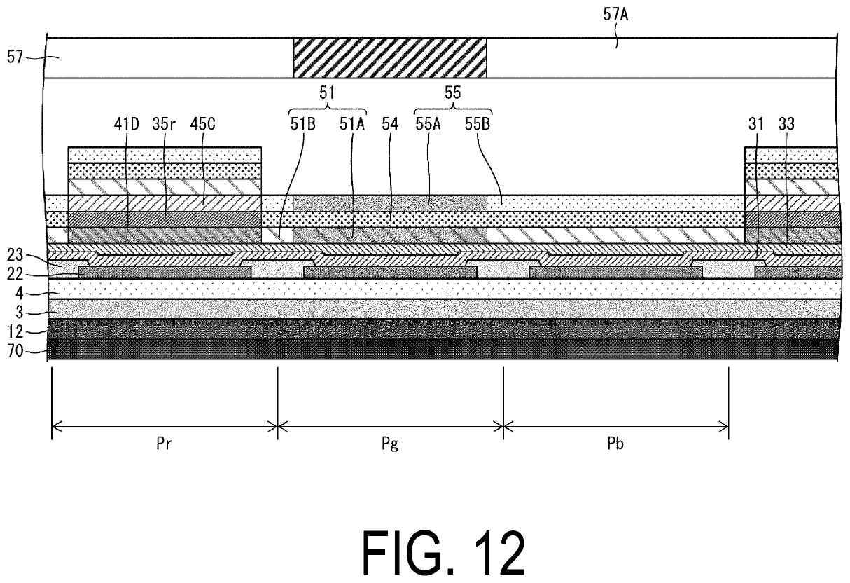

That is, first, as illustrated in FIGS. 6 and 12, a green lower reversal resist layer 51 (second reversal resist) is formed over the entire surface by applying a reversal resist material over the entire surface of the hole transport layer 33 and the soluble portion 45C of the red upper positive resist layer 45 (step S41, part of the second light-emitting layer formation step). Subsequently, a green light-emitting material layer 54 (second light-emitting material layer) is formed on the entire surface of the green lower reversal resist layer 51 by vapor deposition of a material containing a green light-emitting material (light-emitting material of the second light-emitting layer) onto the entire surface of the green lower reversal resist layer 51 or by applying a solution containing a green light-emitting material onto the entire surface of the green lower reversal resist layer 51 and then volatilizing the solvent from the solution (step S42, part of the second light-emitting layer formation step). Subsequently, a positive resist material is applied to the entire surface of the green light-emitting material layer 54 to thereby form a green upper positive resist layer 55 (second positive resist) of a sufficient thickness on the entire surface as will be described later (step S43, part of the second light-emitting layer formation step).

The reversal resist material used in the process P1 in the present step S26 preferably has the same composition as the reversal resist material used in the process P1 in the above-described step S25. This is because the green lower reversal resist layer 51 can be patterned and re-insolubilized under the same conditions as the red lower reversal resist layer 41. The positive resist material used in the process P1 in the present step S26 preferably has the same composition as the positive resist material used in the process P1 in the above-described step S25. This is because the green upper positive resist layer 55 can be patterned under the same conditions as the red upper positive resist layer 45.

In this manner, a layered body (second layered body) is formed including the green lower reversal resist layer 51, the green light-emitting material layer 54, and the green upper positive resist layer 55 in this order from the substrate side.

Next, the layered body described above is subjected to a first exposure with ultraviolet light using a green first mask 57 (step S44, part of the second light-emitting layer formation step). Because the green first mask 57 is used, a portion of the layered body is exposed, and the other portions are not exposed. An optical opening 57A is formed in the green first mask 57 such that a portion corresponding to the formation region of the green light-emitting layer 35g is light-blocking and the other portion is light-transmissive.

As a result, the portions of the green lower reversal resist layer 51 and the green upper positive resist layer 55 that do not correspond to the optical opening 57A (i.e., the portions that overlap the green light-emitting layer 35g) do not undergo the photochemical reaction, and thus remain as insoluble portions 51A and 55A that are insoluble in the developing solution. On the other hand, the other portions corresponding to the optical opening 47A are converted through the photochemical reaction to soluble portions 51B and 55B that are soluble in the developing solution.

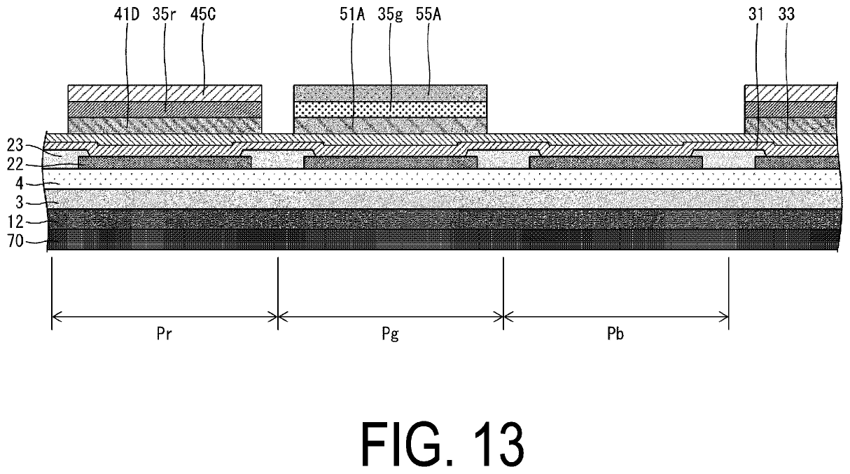

Next, as illustrated in FIGS. 6 and 13, strong developing is carried out (step S45, part of the second light-emitting layer formation step).

As a result, the exposed portion of the layered body including the green light-emitting material layer 54 is removed by removing the soluble portion 51B of the green lower reversal resist layer 51. On the other hand, the insoluble portion 51A of the green lower reversal resist layer 51 remains, and therefore an unexposed portion of the layered body remains. Accordingly, the soluble portions 51B and 55B of the green lower reversal resist layer 51 and the green upper positive resist layer 55 and the portion of the green light-emitting material layer 54 therebetween are removed. On the other hand, the insoluble portions 51A and 55A of the green lower reversal resist layer 51 and the green upper positive resist layer 55 and the portion of the green light-emitting material layer 54 therebetween remain. The remaining portion of the green light-emitting material layer 54 becomes the green light-emitting layer 35g.

At this time, it should be noted that after the soluble portion 55B of the green upper positive resist layer 55 has been removed, the upper surface of the soluble portion 45C of the red upper positive resist layer 45 is exposed to the strong developing solution. Therefore, the soluble portion 45C of the red upper positive resist layer 45 is formed with a sufficient thickness such that in the above-described step S25, protection of the red light-emitting layer 35r by the soluble portion 45C of the red upper positive resist layer 45 can be maintained in the present step S26 (and in the below-described step S27). Further, the re-insoluble portion 41D of the red lower reversal resist layer 41 is insoluble even in a strong developing solution. For these reasons, the red light-emitting layer 35r remains in a protected state as described above, without being removed.

By using the photolithography technique and re-insolubilization of the reversal resist in this manner, the layered body described above is patterned, and as a result, the green light-emitting layer 35g is formed. At the same time, the insoluble portions 51A and 55A of the green lower reversal resist layer 51 and the green upper positive resist layer 55 are formed so as to overlap the green light-emitting layer 35g in a plan view observed from a direction orthogonal to the substrate.

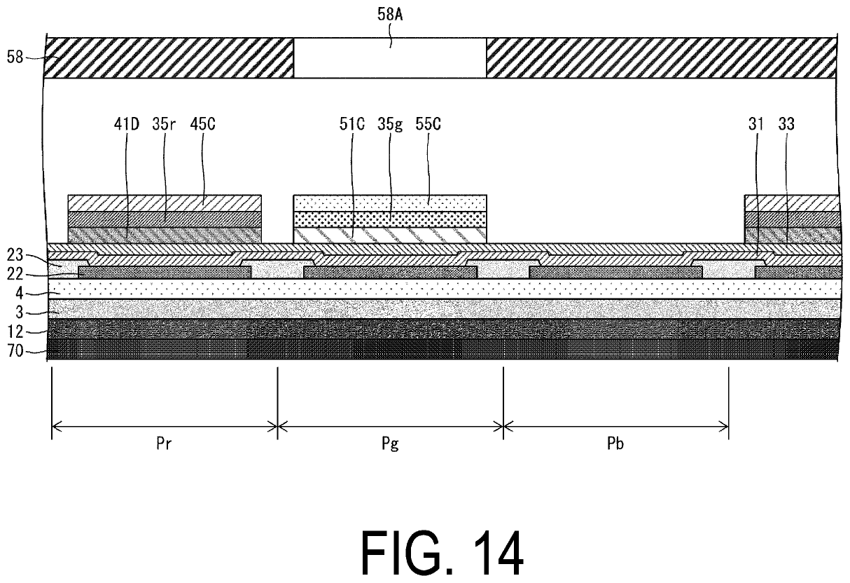

Next, as illustrated in FIGS. 6 and 14, the above-described layered body subjected to patterning is subjected to a second exposure with ultraviolet light using a green second mask 58 (step S46, part of the second re-insolubilization step). An optical opening 58A is formed in the green second mask 58 such that a portion corresponding to the formation region of the green light-emitting layer 35g is light-transmissive and the other portion is light-blocking.

As a result, the insoluble portions 51A and 55A of the green lower reversal resist layer 51 and the green upper positive resist layer 55 are converted through a photochemical reaction to soluble portions 51C and 55C, respectively, the soluble portions 51C and 55C being soluble in the developing solution. Although the second exposure may be carried out without using a mask, use of the green second mask 58 is preferable from the viewpoint of reducing photodegradation.

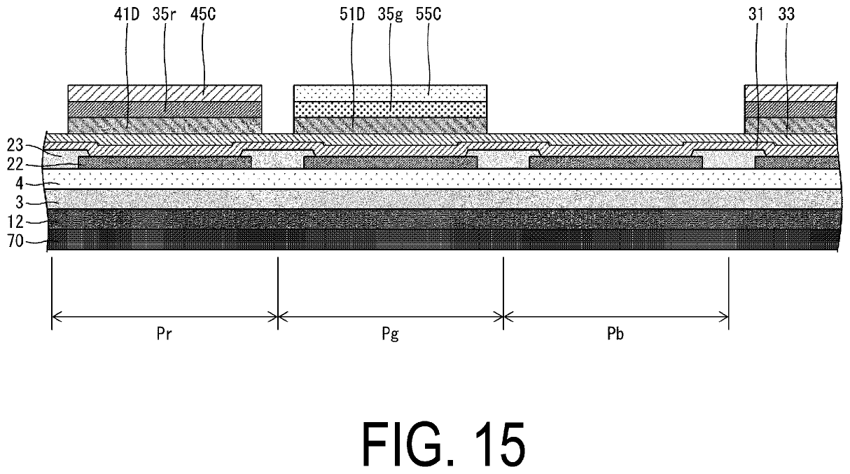

Next, as illustrated in FIGS. 6 and 15, the above-described layered body that was patterned is subjected to reversal firing (step S47, part of the second re-insolubilization step). The reversal firing is heating or laser irradiation carried out such that the green lower reversal resist layer 51 is re-insolubilized without curing the red upper positive resist layer 45 and the green upper positive resist layer 55.

As a result, through decarboxylation, the soluble portion 51C of the green lower reversal resist layer 51 becomes a re-insoluble portion 51D that is insoluble in the developing solution. On the other hand, the soluble portion 55C of the green upper positive resist layer 55 remains as the soluble portion 55C.

In step S26, as described above, the green light-emitting layer 35g is formed in a state of being sandwiched and protected between the re-insoluble portion 51D of the green lower reversal resist layer 51 and the soluble portion 55C of the green upper positive resist layer 55.

### Process Including Formation of Blue Light-Emitting Layer

Next, as illustrated in FIG. 5 and FIGS. 16 to 18, a process that includes formation of the blue light-emitting layer 35b is carried out (step S27). In step S27, the process P2 described in FIG. 7 is executed.

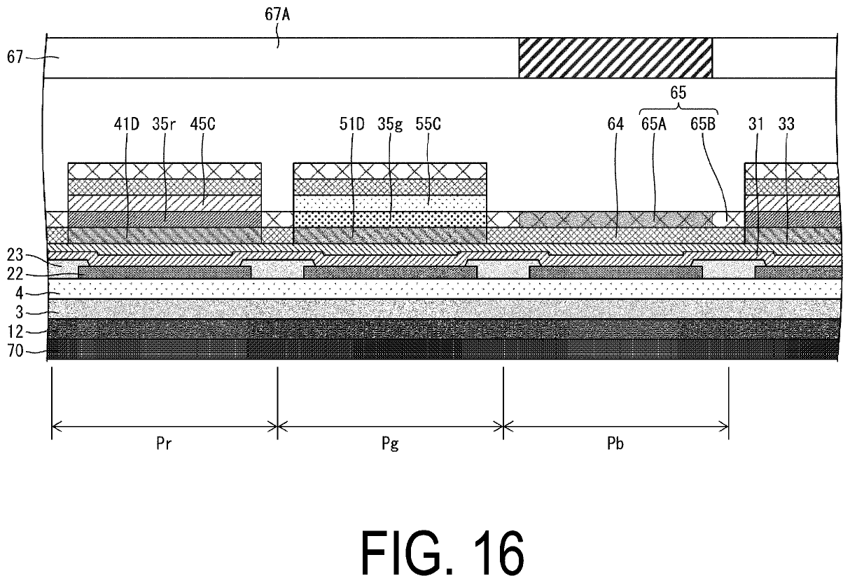

First, as illustrated in FIGS. 7 and 16, a blue light-emitting material layer 64 (third light-emitting material layer) is formed on the entire surfaces of the hole transport layer 33 and the soluble portions 45C and 55C of the red upper positive resist layer 45 and the green upper positive resist layer 55 by vapor deposition of a material containing a blue light-emitting material (light-emitting material of the third light-emitting layer) onto the entire surfaces thereof or by applying a solution containing a blue light-emitting material onto the entire surfaces thereof and then volatilizing the solvent from the solution (step S42, part of the third light-emitting layer formation step). Subsequently, a positive resist material is applied to the entire surface of the blue light-emitting material layer 64 to thereby form a blue upper positive resist layer 65 (third positive resist) on the entire surface (step S43, part of the third light-emitting layer formation step).

The positive resist material used in the process P1 in the present step S27 preferably has the same composition as the positive resist material used in the process P1 in the above-described steps S25 and S26. This is because the blue upper positive resist layer 65 can be patterned under the same conditions as the red upper positive resist layer 45 and the green upper positive resist layer 55.

In this manner, a layered body (third layered body) is formed including the blue light-emitting material layer 64 and the blue upper positive resist layer 65 in this order from the substrate side.

Next, the layered body described above is subjected to a first exposure with ultraviolet light using a blue first mask 67 (step S44, part of the third light-emitting layer formation step). Because the blue first mask 67 is used, a portion of the layered body is exposed, and the other portions are not exposed. An optical opening 67A is formed in the blue first mask 67 such that a portion corresponding to the formation region of the blue light-emitting layer 35b is light-blocking and the other portion is light-transmissive.

As a result, the portions of the blue lower reversal resist layer 61 and the blue upper positive resist layer 65 that do not correspond to the optical opening 67A (i.e., the portions that overlap the blue light-emitting layer 35b) do not undergo the photochemical reaction, and thus remain as insoluble portions 61A and 65A, respectively, the insoluble portions 61A and 65A being insoluble in the developing solution. On the other hand, the other portions corresponding to the optical opening 67A are converted through the photochemical reaction to soluble portions 61B and 65B that are soluble in the developing solution.

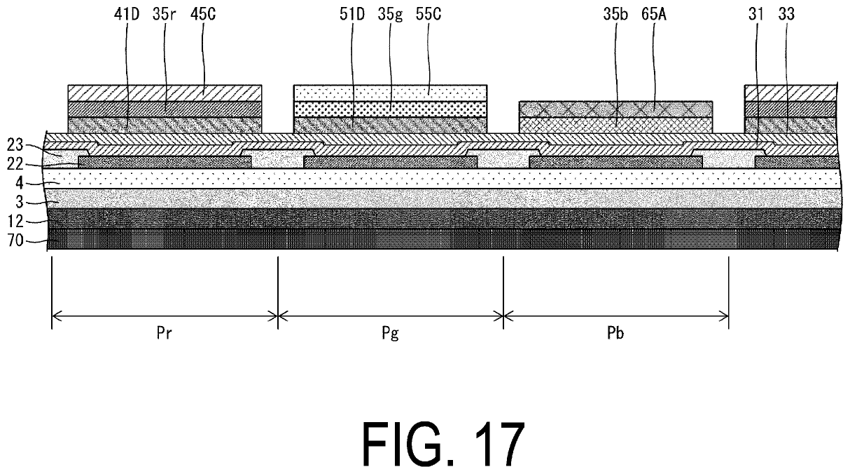

Next, as illustrated in FIGS. 7 and 17, strong developing is carried out (step S45, part of the third light-emitting layer formation step).

As a result, the soluble portion 65B of the blue upper positive resist layer 65 is removed, and the soluble portions 45C and 55C of the red upper positive resist layer 45 and the green upper positive resist layer 55 are partially removed. Through this, the exposed portion of the layered body including the blue light-emitting material layer 64 is removed. The insoluble portion 65A of the blue upper positive resist layer 65 remains, and therefore the unexposed portion of the layered body remains. Accordingly, the soluble portion 65B of the blue upper positive resist layer 65 and the underlying portion of the blue light-emitting material layer 64 are removed. On the other hand, the insoluble portion 65A of the blue upper positive resist layer 65 and the underlying portion of the blue light-emitting material layer 64 remain. The remaining portion of the blue light-emitting material layer 64 becomes the blue light-emitting layer 35b.

As a result, the exposed portion of the layered body including the green light-emitting material layer 54 is removed by removing the soluble portion 51B of the green lower reversal resist layer 51. On the other hand, the insoluble portion 51A of the green lower reversal resist layer 51 remains, and therefore an unexposed portion of the layered body remains.

At this time, it should be noted that after the soluble portion 65B of the blue upper positive resist layer 65 has been removed, the upper surfaces of the soluble portions 45C and 55C of the red upper positive resist layer 45 and the green upper positive resist layer 55 are exposed to the strong developing solution. Therefore, the soluble portion 45C of the red upper positive resist layer 45 is formed in step S25 with a sufficient thickness such that in the present step S27, protection of the red light-emitting layer 35r by the soluble portion 45C of the red upper positive resist layer 45 can be maintained. The red light-emitting layer 35r is in a state of being sandwiched and protected between the re-insoluble portion 41D of the red lower reversal resist layer 41 and the soluble portion 45C of the red upper positive resist layer 45. Similarly, the soluble portion 55C of the green upper positive resist layer 55 is formed in step S26 with a sufficient thickness such that protection of the green light-emitting layer 35g by the soluble portion 55C of the green upper positive resist layer 55 can be maintained in the present step S27. Further, the re-insoluble portions 41D and 51D of the red lower reversal resist layer 41 and the green lower reversal resist layer 51 are insoluble even in a strong developing solution. For these reasons, the red light-emitting layer 35r and the green light-emitting layer 35g remain in a protected state as described above, without being removed.

By using the photolithography technique and re-insolubilization of the reversal resist in this manner, the layered body described above is patterned, and as a result, the blue light-emitting layer 35b is formed. At the same time, the insoluble portion 65A of the blue upper positive resist layer 65 is formed so as to overlap the blue light-emitting layer 35b in a plan view observed from a direction orthogonal to the substrate.

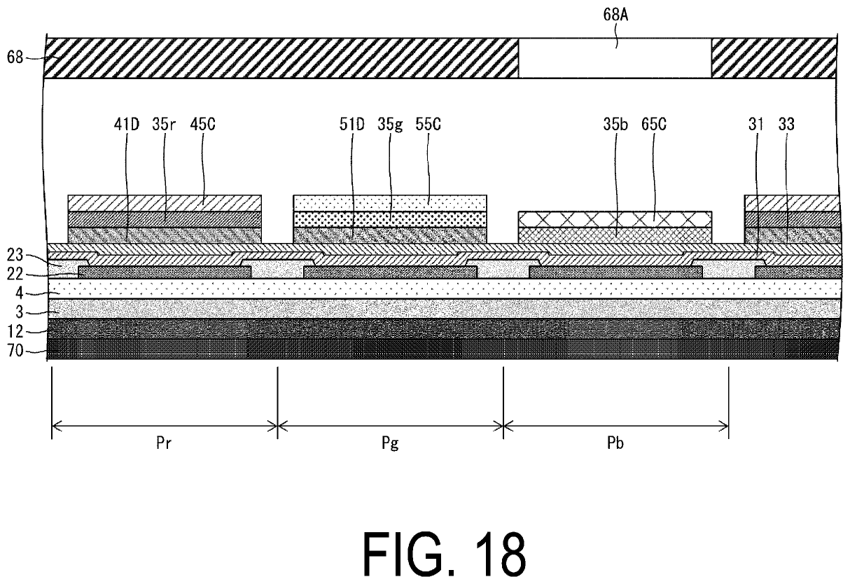

Next, as illustrated in FIGS. 7 and 18, the above-described layered body subjected to patterning is subjected to a second exposure with ultraviolet light using a blue second mask 68 (step S46). An optical opening 68A is formed in the blue second mask 68 such that a portion corresponding to the blue light-emitting layer 35b is light-transmissive and the other portion is light-blocking.

As a result, the insoluble portion 65A of the blue upper positive resist layer 65 is converted through a photochemical reaction to a soluble portion 65C that is soluble in the developing solution. Although the second exposure may be carried out without using a mask, use of the blue second mask 68 is preferable from the viewpoint of reducing photodegradation.

In step S27, as described above, the blue light-emitting layer 35b is formed in a state of being covered and protected under the soluble portion 65C of the blue upper positive resist layer 65.

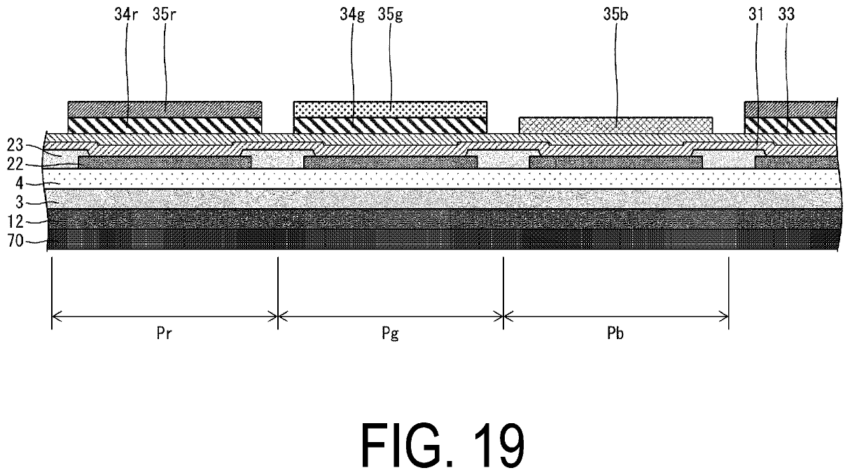

Next, as illustrated in FIG. 5 and FIG. 19, development is carried out using a weak developing solution. (Step S28, Positive Resist Removal Step) In the present specification, the term “weak developing solution” means an above-mentioned developing solution that (i) can dissolve the entire soluble portion of the resist layer above the light-emitting material layer (or light-emitting layer) by dissolving the soluble portion of the resist layer from the upper surface and the side surface, but (ii) cannot dissolve the entire soluble portion of the resist layer below the light-emitting material layer by dissolving, from the side surface, the soluble portion thereof, and as a result, (iii) cannot release the light-emitting material layer. The weak developing solution is, for example, a diluted alkaline aqueous solution to which a surfactant is not added or an organic solvent to which a surfactant is not added. The pH of the diluted alkaline aqueous solution is, for example, from 7 to less than 11.

As a result, the soluble portions 45C, 55C and 65C of the red upper positive resist layer 45, the green upper positive resist layer 55, and the blue upper positive resist layer 65 are removed from the upper layers of the respective light-emitting layers 35. On the other hand, each light-emitting layer 35 remains. In addition, re-insoluble portions 41D and 51D of the red lower reversal resist layer 41 and the green lower reversal resist layer 51 remain.

Next, a main firing is carried out (step S29). As a result, the re-insoluble portions 41D and 51D of the red lower reversal resist layer 41 and the green lower reversal resist layer 51 are cured and become a red lower resin layer 34r and a green lower resin layer 34g, respectively.

Next, as illustrated in FIG. 5, the electron transport layer 37 is formed on the entire surface of the light-emitting layer 35 (step S30), and the cathode 25 is formed on the entire surface of the electron transport layer 37 (step S31). In this manner, the light-emitting element layer 5 illustrated in FIG. 4 is formed.

### First Modified Example

In the method according to the first embodiment, step S29 (see FIG. 5) may optionally be omitted. If step S29 is not carried out, the re-insoluble portions 41D and 51D remain uncured and become the red lower resin layer 34r and the green lower resin layer 34g.

### Second Modified Example

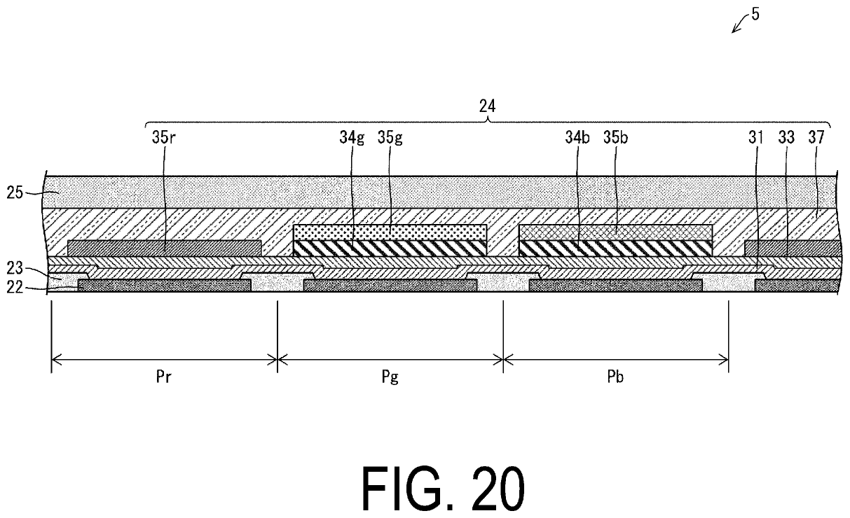

FIG. 20 is a schematic cross-sectional view illustrating another example of a configuration of the light-emitting element layer 5 in the display device 2 (light-emitting device) according to the first embodiment.

In the method according to the first embodiment, the order in which steps S25 to S27 (see FIG. 5) are implemented can be changed. When the order is changed, the process P2 described in FIG. 7 is executed in the step that is implemented last among steps S25 to S27, and the process P1 described in FIG. 6 is executed in the steps that are implemented other than the last step. As a result, the lower resin layer 34 is not formed under the light-emitting layer of the color formed last among the light-emitting layers 35, and the lower resin layer 34 is formed under the light-emitting layers of the other colors.

For example, of steps S25 to S27, step S25 may be implemented last. In this case, as illustrated in FIG. 20, the red lower resin layer is not formed below the red light-emitting layer 35r, and instead, the blue lower resin layer 34b is formed below the blue light-emitting layer 35b. In this case, the green lower resin layer 34g and the blue lower resin layer 34b are collectively referred to as a “lower resin layer 34”.

### Third Modified Example

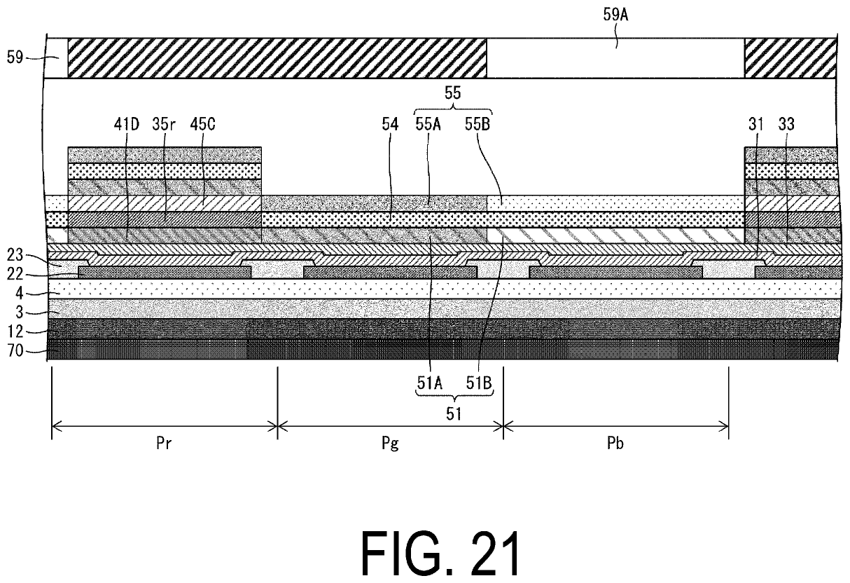

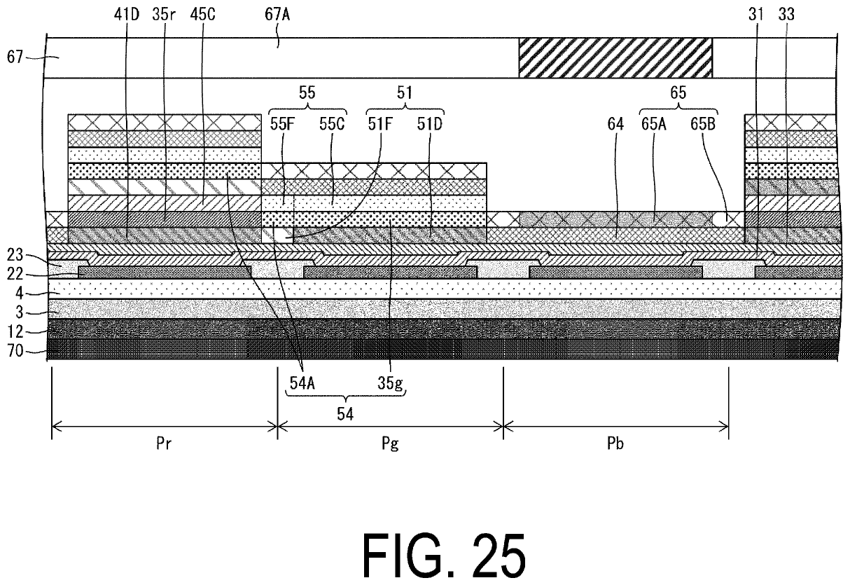

FIGS. 21 to 25 are each a schematic cross-sectional view illustrating another example of a step (step S4) of forming, on a substrate, the example of the light-emitting element layer 5 illustrated in FIG. 4.

With the method according to the first embodiment, the last step among the plurality of steps in which the process P1 is implemented can use, in the first exposure (step S44) in the process P1 described in FIG. 6, a third mask differing from the first mask and the second mask. In the third mask, at least a portion corresponding to the formation region of the light-emitting layer formed in the last step has a light blocking property. In addition, in the third mask, any optionally selected portion corresponding to a formation region of the light-emitting layer formed in advance may have a light blocking property, and any optionally selected portion corresponding to a gap region between the formation regions of the light-emitting layer may have a light blocking property.

For example, a case in which the process P1 is implemented in step S25, the process P1 is implemented in step S26, and next, the process P2 is implemented in step S27 is presented as an example. In this example, in step S26, the process P1 is carried out as illustrated in FIGS. 21 to 24 instead of FIGS. 12 to 15.

First, as illustrated in FIGS. 6 and 21, a layered body is formed including the green lower reversal resist layer 51, the green light-emitting material layer 54, and the green upper positive resist layer 55 in this order from the substrate side (steps S41 to S43). Next, the layered body is subjected to a first exposure with ultraviolet light using a green third mask 59 (step S44). In the green third mask 59, a portion corresponding to a formation region of the green light-emitting layer 35g has a light blocking property. In addition, in the green third mask 59, a portion corresponding to the formation region of the red light-emitting layer 35r and a portion corresponding to a gap region between the formation regions of the red light-emitting layer 35r and the green light-emitting layer 35g are light-blocking. An optical opening 59A is formed in the green third mask 59 such that the other portion is light-transmissive.

As a result, in addition to the portions of the green lower reversal resist layer 51 and the green upper positive resist layer 55 that overlap the green light-emitting layer 35g, the portion that overlaps red light-emitting layer 35r and a portion that corresponds to the gap between red light-emitting layer 35r and green light-emitting layer 35g do not undergo a photochemical reaction, and thus remain as insoluble portions 51A and 55A, respectively, the insoluble portions 51A and 55A being insoluble in the developing solution. On the other hand, the other portions are converted through the photochemical reaction to soluble portions 51B and 55B that are soluble in the developing solution.

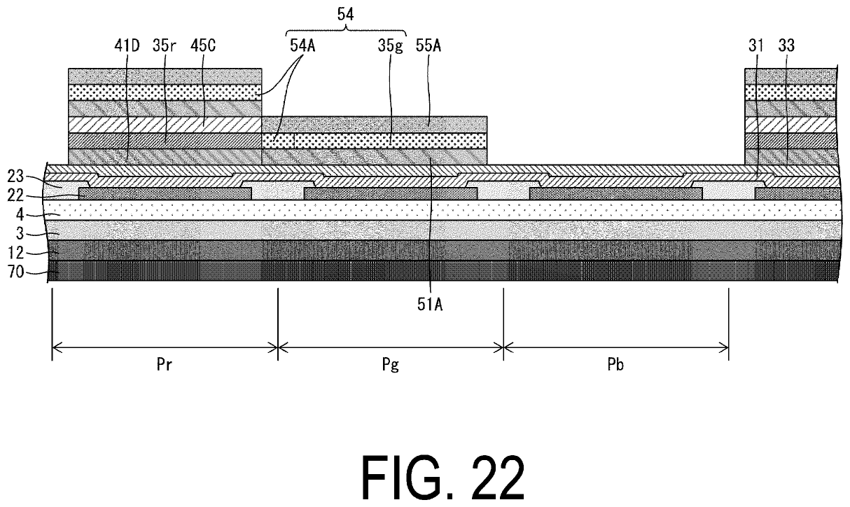

Next, as illustrated in FIGS. 6 and 22, development is carried out using a strong developing solution (step S45). As a result, the insoluble portions 51A and 55A of the green lower reversal resist layer 51 and the green upper positive resist layer 55, and the portion of the green light-emitting material layer 54 therebetween remain. In the present modified example, of the remaining portion of the green light-emitting material layer 54, the portion corresponding to the formation region of the green light-emitting layer 35g becomes the green light-emitting layer 35g, while a surplus portion 54A that does not correspond thereto is finally removed.

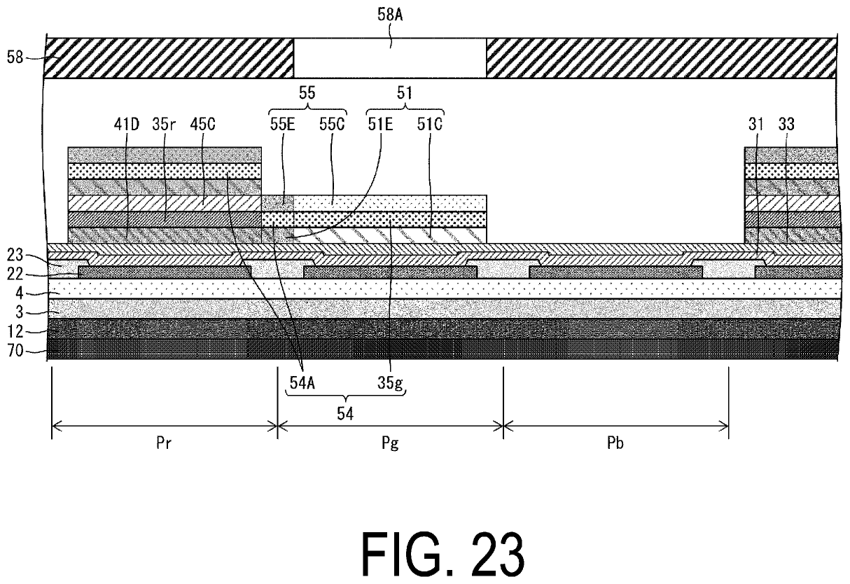

Next, as illustrated in FIGS. 6 and 23, the layered body subjected to patterning is subjected to a second exposure with ultraviolet light using a green second mask 58 (step S46).

As a result, the exposed portions of the insoluble portions 51A and 55A of the green lower reversal resist layer 51 and the green upper positive resist layer 55 are converted through a photochemical reaction to soluble portions 51C and 55C, respectively, the soluble portions 51C and 55C being soluble in the developing solution. The unexposed portions of the insoluble portions 51A and 55A remain insoluble in the developing solution without undergoing a photochemical reaction. Here, the unexposed portions of the insoluble portions 51A and 55A are referred to as insoluble portions 51E and 55E.

It should be noted that unlike the case in which the green first mask 57 was used in the first exposure, in the second exposure (step S46), a mask must be used in which an opening is formed such that the portion corresponding to the surplus portion 54A of the green light-emitting material layer 54 has a light-blocking property and the portion corresponding to the green light-emitting layer 35g has a light-transmitting property.

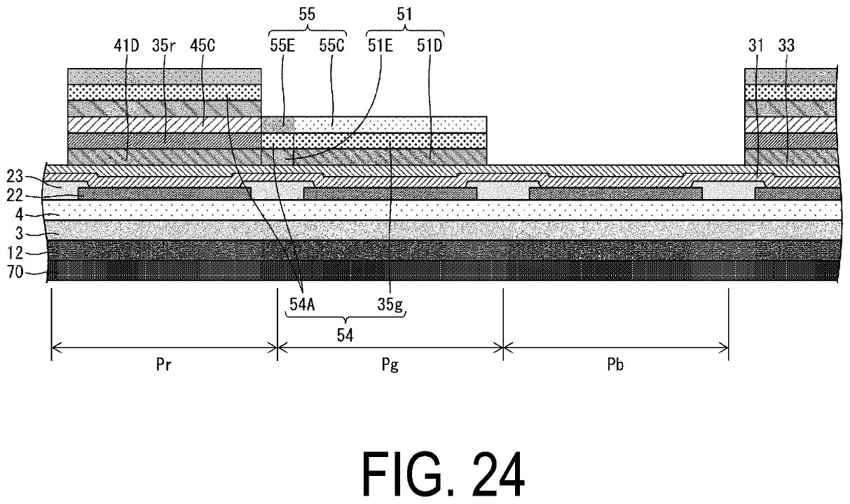

Next, as illustrated in FIGS. 6 and 24, the patterned layered body is subjected to reversal firing (step S47).

As a result, through decarboxylation, the soluble portion 51C of the green lower reversal resist layer 51 becomes a re-insoluble portion 51D that is insoluble in the developing solution. On the other hand, the soluble portion 55C of the green upper positive resist layer 55 remains as the soluble portion 55C. Similarly, the insoluble portions 51E and 55E of the green lower reversal resist layer 51 and the green upper positive resist layer 55 remain as the insoluble portions 51E and 55E.

Next, the process advances to a step of forming the blue light-emitting layer 35b (step S27 in FIG. 5), and as illustrated in FIGS. 6, 7, and 25, a layered body is formed including the blue light-emitting material layer 64 and the blue upper positive resist layer 65 in this order from the substrate side (steps S42 to S43). Next, the layered body is subjected to a first exposure with ultraviolet light using a blue first mask 67 (step S44).

As a result, the portions of the blue lower reversal resist layer 61 and the blue upper positive resist layer 65 that do not overlap with the blue light-emitting layer 35b are converted, through a photochemical reaction, to soluble portions 61B and 65B that are soluble in the developing solution. At the same time, the insoluble portions 51E and 55E of the green lower reversal resist layer 51 and the green upper positive resist layer 55 are converted through a photochemical reaction to soluble portions 51F and 55F that are soluble in the developing solution.

Next, strong developing is carried out (step S45).

As a result, the soluble portions 61B and 65B of the blue lower reversal resist layer 61 and the blue upper positive resist layer 65, and the portion of the blue light-emitting material layer 64 therebetween are removed. At the same time, the soluble portions 51F and 55F of the green lower reversal resist layer 51 and the green upper positive resist layer 55, and the portion of the green light-emitting material layer 54 therebetween are removed.

Accordingly, through the above-described process, a layered body having a structure similar to the structure of the layered body with respect to each subpixel can be obtained as illustrated in FIG. 17.

### Fourth Modified Example

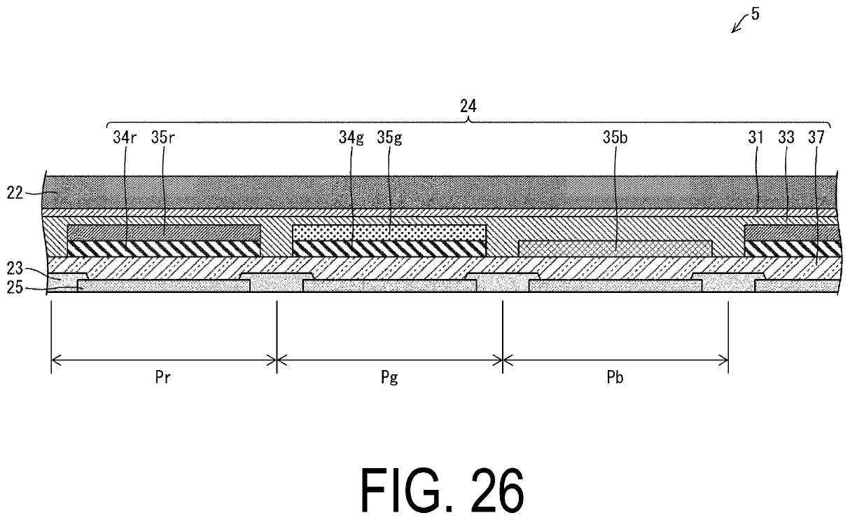

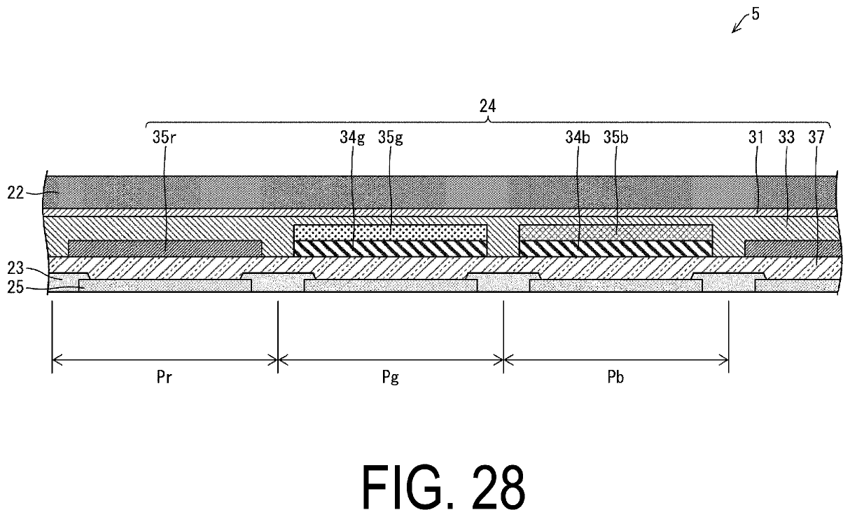

FIGS. 26 and 28 are each a schematic cross-sectional view illustrating yet another example of a configuration of the light-emitting element layer 5 in the display device 2 (light-emitting device) according to the first embodiment.

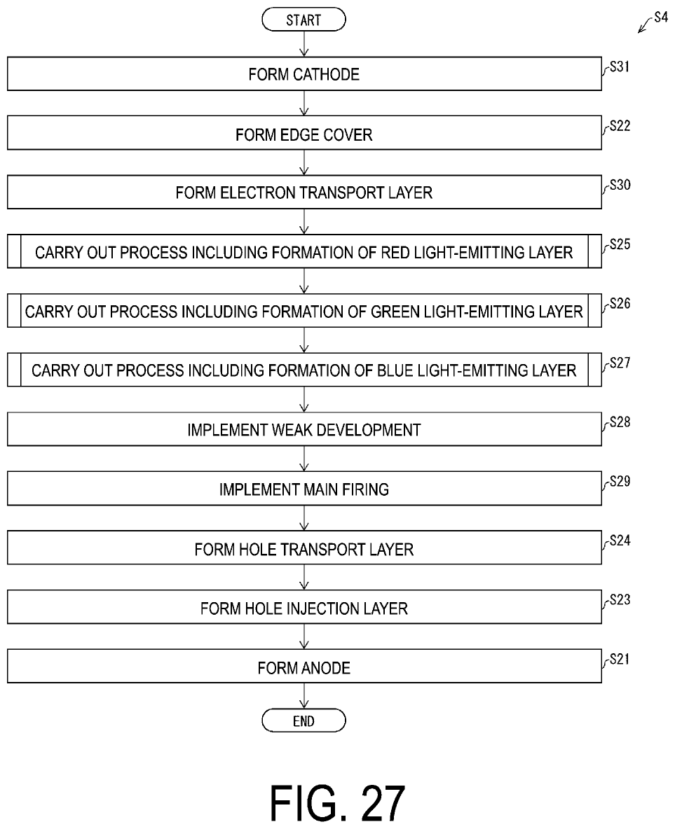

FIG. 27 is a schematic flowchart describing an example of a step (step S4) of forming, on a substrate, the example of the light-emitting element layer 5 illustrated in FIG. 26.

As illustrated in FIG. 26, the light-emitting element layer 5 may include, in order from the substrate side, a cathode 25 (first lower layer electrode), an electron transport layer 37, a lower resin layer 34 (photosensitive resin), a light-emitting layer 35, a hole transport layer 33, a hole injection layer 31, and an anode 22 (first upper layer electrode).

In this case, as described in FIG. 27, in the step (step S4) of forming the light-emitting element layer 5, the cathode 25 is formed in an island shape for each region of each subpixel P (step S31), the edge cover 23 is formed so as to cover the edge of the cathode 25 (step S22), the electron transport layer 37 is formed over the entire surface (step S30), a process including formation of the red light-emitting layer 35r is carried out (step S25), a process including formation of the green light-emitting layer 35g is carried out (step S26), a process including formation of the blue light-emitting layer 35b is carried out (step S27), weak development is carried out (step S28), the main firing is implemented (step S29), the hole transport layer 33 is formed over the entire surface (step S24), the hole injection layer 31 is formed over the entire surface (step S23), and the anode 22 is formed over the entire surface (step S21).

In this case as well, the order in which steps S25 to S27 are implemented can be changed. The process P2 described in FIG. 7 is executed in the last step implemented among the steps S25 to S27, and the process P1 described in FIG. 6 is executed in the other steps. For example, step S25 may be implemented last. In this case, as illustrated in FIG. 28, the red lower resin layer is not formed below the red light-emitting layer 35r, and instead, the blue lower resin layer 34b is formed below the blue light-emitting layer 35b.

### Fifth Modified Example

In step S42 executed in step S25, the red light-emitting material layer 44 may be formed by applying a solution containing a light-emitting material and a positive resist onto the entire surface and then volatilizing the solvent from the solution. In this case, in step S44, the positive resist included in the portion of the red light-emitting material layer 44 corresponding to a region other than the formation region of the red light-emitting layer 35r becomes soluble in the developing solution. Therefore, in the subsequent step S45, the portion of the red light-emitting material layer 44 corresponding to the region other than the formation region of the red light-emitting layer 35r is more easily removed than in a case in which the red light-emitting material layer 44 is formed from a solution not containing a positive resist.

As a result, in step S45, development can be implemented using a slightly strong developing solution. In the present specification, the term “slightly strong developing solution” means an above-mentioned developing solution that (i) can dissolve the entire soluble portion of the resist layer above the light-emitting material layer (or light-emitting layer) by dissolving the soluble portion of the resist layer from the upper surface and the side surface, and (ii) can dissolve or permeate the light-emitting material layer formed from a solution containing a positive resist, and as a result, (iii) can dissolve the entire soluble portion of the resist layer below the light-emitting material layer by dissolving the soluble portion from the upper surface and the side surface. The slightly strong developing solution is, for example, a slightly concentrated alkaline aqueous solution, a diluted alkaline solution to which a surfactant is added at a low concentration, or an organic solvent to which a surfactant is added at a low concentration. The pH of the slightly concentrated alkaline aqueous solution is, for example, from 11 to less than 12. The low concentration is, for example, less than 0.5 wt. %.

By using a slightly strong developing solution, the damage to each layer or each member can be reduced in comparison to a case in which a strong developing solution is used.

In addition, in the display device 2, the red light-emitting layer 35r contains a positive-type photosensitive resin derived from a positive resist.

Similarly, in each step S42 executed in step S26 and step S27, the green light-emitting material layer 54 and the blue light-emitting material layer 64 may be formed by applying solutions containing a light-emitting material and a positive resist onto the entire surface and then volatilizing the solvent from the solution.

### Sixth Modified Example

An example in which two of the three subpixels of the red subpixel Pr, the green subpixel Pg, and the blue subpixel Pb are provided with the lower resin layer was described above. However, the scope of the present embodiment is not limited thereto, and examples ranging from an example in which only one of the quantity of N light-emitting elements is provided with a lower resin layer to an example in which only a quantity of (N−1) of the quantity of N light-emitting elements is provided with the lower resin layer are included in the present first embodiment. Here, N is an integer of 2 or greater.

The above-described First to Sixth Modified Examples can be mutually combined in any combination. In addition, the above-described First to Fifth Modified Examples and any combinations thereof can be applied to a below-described second embodiment. In addition, the above-described Second to Sixth Modified Examples and any combinations thereof can be applied to a below-described third embodiment. Moreover, the above-described First to Sixth Modified Examples and any combinations thereof can be applied to a below-described fourth embodiment.

### Energy Level of Light-Emitting Element Layer

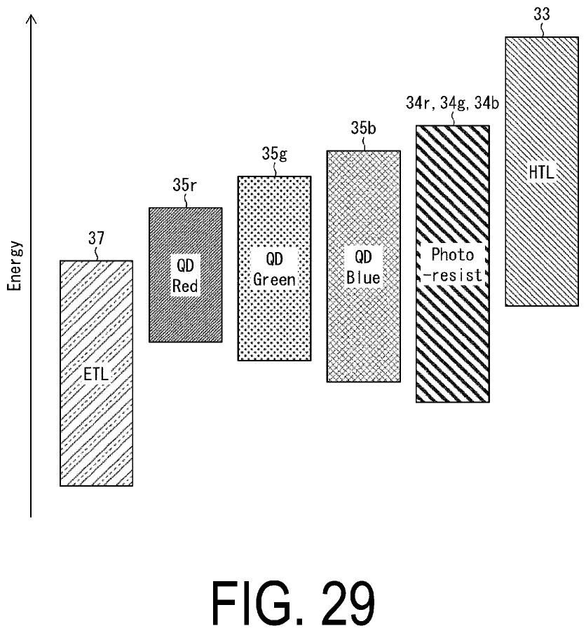

Hereinafter, the band gap of the lower resin layer 34 according to the present embodiment will be described in detail with reference to FIGS. 29 to 34.

FIG. 29 is a schematic energy level diagram illustrating an example of band gaps of the hole transport layer 33, the lower resin layer 34, the light-emitting layer 35, and the electron transport layer 37 of the light-emitting element layer 5 illustrated in FIG. 4.

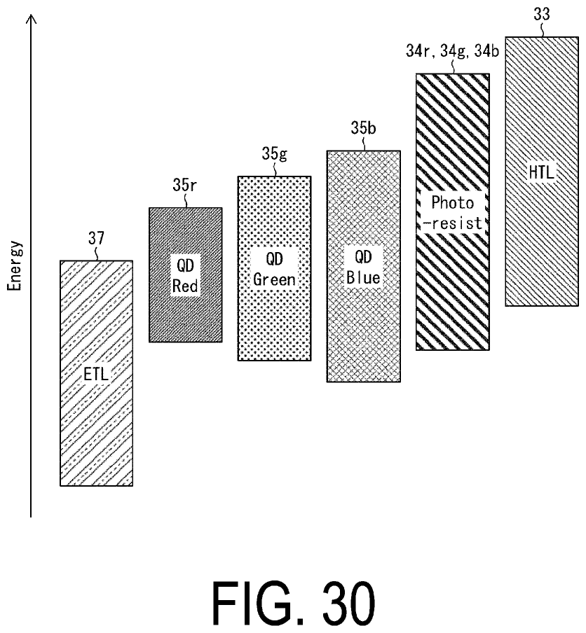

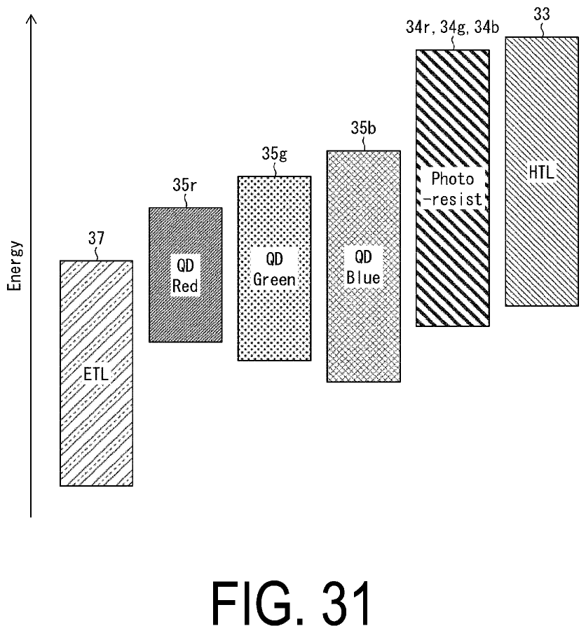

FIGS. 30 and 31 are each a schematic energy level diagram illustrating an example of band gaps of the hole transport layer 33, the lower resin layer 34, the light-emitting layer 35, and the electron transport layer 37 of the light-emitting element layer 5 illustrated in FIG. 20.

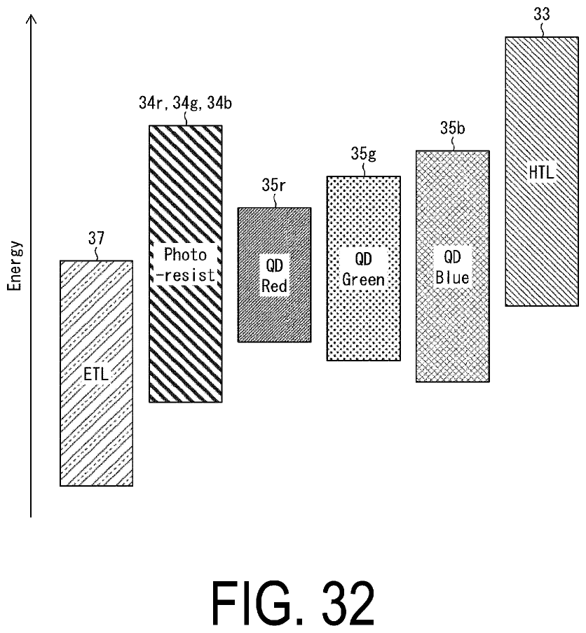

FIG. 32 is a schematic energy level diagram illustrating the band gaps of the hole transport layer 33, the lower resin layer 34, the light-emitting layer 35, and the electron transport layer 37 of the light-emitting element layer 5 illustrated in FIG. 26.

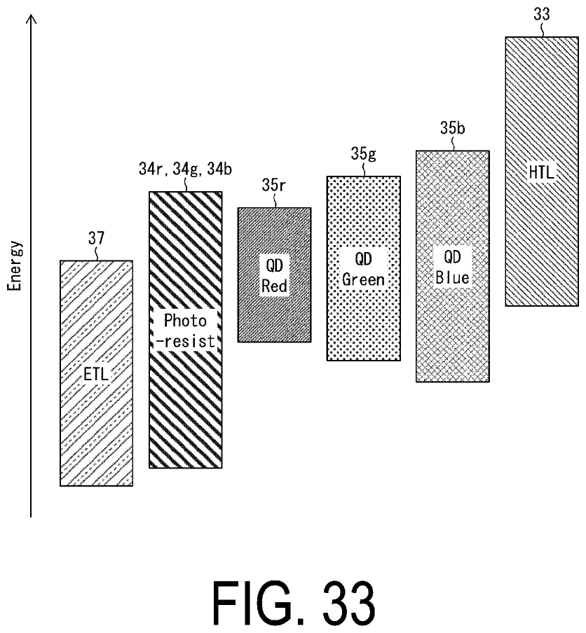

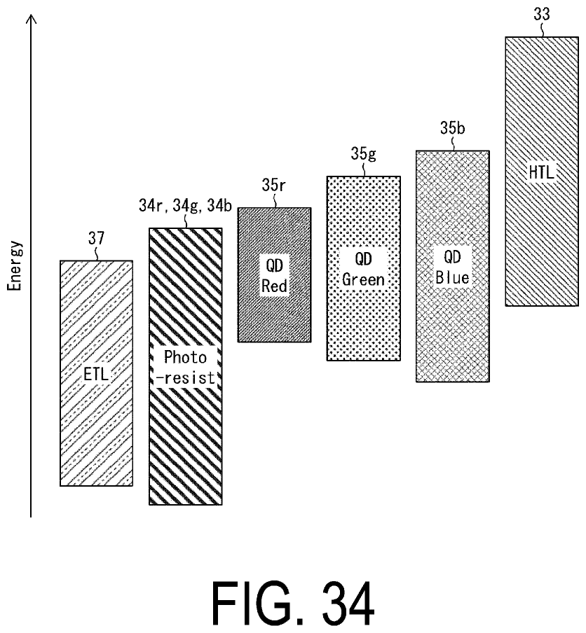

FIGS. 33 and 34 are each a schematic energy level diagram illustrating band gaps of the hole transport layer 33, the lower resin layer 34, the light-emitting layer 35, and the electron transport layer 37 of the light-emitting element layer 5 illustrated in FIG. 28.

Each of FIGS. 29 to 34 illustrates the conduction band at the upper side and the valence band at the lower side. Hereinafter, a state in which the lowest unoccupied molecular orbital (LUMO) or the lower end of the conduction band, or the highest occupied molecular orbital (HOMO) or the upper end of the valence band is close to the energy level of a vacuum state (that is, a state of being located at the upper side in FIGS. 29 to 34, and having a small electron affinity or ionization energy) is expressed as “shallow”. Further, a state of being far from the energy level of a vacuum state (that is, a state of being located at the lower side in FIGS. 29 to 34 and having a large electron affinity or ionization energy) is expressed as “deep”.

In the configuration in which the lower resin layer 34 is located between the hole transport layer 33 and the light-emitting layer 35 as illustrated in FIGS. 4 and 20, the HOMO of the lower resin layer 34 must be deeper than the HOMO of the hole transport layer 33 as illustrated in FIGS. 29 to 31. This is because when the HOMO of the lower resin layer 34 is equal to or shallower than the HOMO of the hole transport layer 33, positive holes moving from the hole transport layer 33 toward the light-emitting layer 35 are trapped in the lower resin layer 34.

In a configuration like those illustrated in FIGS. 4 and 20, when the HOMO of the red lower resin layer 34r is deeper than the HOMO of the hole transport layer 33 and is deeper than the upper end of the valence band of the red light-emitting layer 35r, the red lower resin layer 34r can function as a layer that inhibits hole injection from the hole transport layer 33 to the red light-emitting layer 35r. As a result, excess injection of positive holes can be reduced. On the other hand, when the HOMO of the red lower resin layer 34r is deeper than the HOMO of the hole transport layer 33 and is shallower than the upper end of the valence band of the red light-emitting layer 35r, the red lower resin layer 34r can function as a layer that assists in hole injection from the hole transport layer 33 to the red light-emitting layer 35r. The same applies to the green lower resin layer 34g and the blue lower resin layer 34b.

In the configuration illustrated in FIG. 4, the HOMO of the lower resin layer 34 is preferably deeper than the upper end of the valence band of the blue light-emitting layer 35b as illustrated in FIG. 29. Through such a configuration, movement of positive holes from the hole transport layer 33 to the red light-emitting layer 35r and the green light-emitting layer 35g is inhibited. In other words, in a configuration in which a lower resin layer is not formed between the hole transport layer and the light-emitting layer having the deepest valence band upper end among the plurality of different light-emitting layers, and a lower resin layer is formed between the hole transport layer and the other light-emitting layers, the HOMO of the lower resin layer is preferably deeper than the valence band upper end of the light-emitting layer having the deepest valence band upper end among the plurality of different light-emitting layers.

In the configuration illustrated in FIG. 20, the HOMO of the lower resin layer 34 is preferably shallower than the upper end of the valence band of the blue light-emitting layer 35b as illustrated in FIGS. 30 and 31. In this case, the HOMO of the hole transport layer 33, the HOMO of the blue lower resin layer 34b, and the upper end of the valence band of the blue light-emitting layer 35b are arranged in a stepwise manner in this order. As a result, movement of positive holes from the hole transport layer 33 to the blue light-emitting layer 35b is promoted. In other words, in a configuration in which a lower resin layer is not formed between the hole transport layer and the light-emitting layer having the shallowest valence band upper end among the plurality of different light-emitting layers, and a lower resin layer is formed between the hole transport layer and the other light-emitting layers, the HOMO of the lower resin layer is preferably shallower than the valence band upper end of the light-emitting layer having the deepest valence band upper end among the plurality of different light-emitting layers.

In a configuration in which the lower resin layer 34 is located between the electron transport layer 37 and the light-emitting layer 35 as illustrated in FIGS. 26 and 28, the LUMO of the lower resin layer 34 must be shallower than the LUMO of the electron transport layer 37 as illustrated in FIGS. 32 to 34. This is because when the LUMO of the lower resin layer 34 is equal to or deeper than the LUMO of the electron transport layer 37, electrons moving from the electron transport layer 37 toward the light-emitting layer 35 are trapped in the lower resin layer 34.

In a configuration like those illustrated in FIGS. 26 and 28, when the LUMO of the red lower resin layer 34r is shallower than the LUMO of the electron transport layer 37 and is shallower than the lower end of the conduction band of the red light-emitting layer 35r, the red lower resin layer 34r can function as a layer that inhibits the injection of electrons from the electron transport layer 37 into the red light-emitting layer 35r. As a result, excessive injection of electrons can be reduced. On the other hand, when the LUMO of the red lower resin layer 34r is shallower than the LUMO of the electron transport layer 37 and is deeper than the lower end of the conduction band of the red light-emitting layer 35r, the red lower resin layer 34r can function as a layer that assists in the injection of electrons from the electron transport layer 37 into the red light-emitting layer 35r. The same applies to the green lower resin layer 34g and the blue lower resin layer 34b.

In the configuration illustrated in FIG. 26, the LUMO of the lower resin layer 34 is preferably shallower than the lower end of the conduction band of the blue light-emitting layer 35b as illustrated in FIG. 32. Through such a configuration, movement of electrons from the electron transport layer 37 to the red light-emitting layer 35r and the green light-emitting layer 35g is inhibited. In other words, in a configuration in which a lower resin layer is not formed between the electron transport layer and the light-emitting layer having the shallowest conduction band lower end among the plurality of different light-emitting layers, and a lower resin layer is formed between the other light-emitting layers and the electron transport layer, the LUMO of the lower resin layer is preferably shallower than the conduction band lower end of the light-emitting layer having the shallowest conduction band lower end among the plurality of different light-emitting layers.

In the configuration illustrated in FIG. 28, the LUMO of the lower resin layer 34 is preferably deeper than the lower end of the conduction band of the blue light-emitting layer 35b as illustrated in FIGS. 33 and 34. Through such a configuration, the LUMO of the electron transport layer 37, the LUMO of the blue lower resin layer 34b, and the lower end of the conduction band of the blue light-emitting layer 35b are arranged in this order in a stepwise manner. As a result, movement of electrons from the electron transport layer 37 to the blue light-emitting layer 35b is promoted. In other words, in a configuration in which a lower resin layer is not formed between the electron transport layer and the light-emitting layer having the deepest conduction band lower end among the plurality of different light-emitting layers, and a lower resin layer is formed between the other light-emitting layers and the hole transport layer, the LUMO of the lower resin layer is preferably deeper than the conduction band lower end of the light-emitting layer having the shallowest conduction band lower end among the plurality of different light-emitting layers.

### Action and Effects

According to the method of the first embodiment, the layer containing the quantum dots and the layer containing the photoresist are separate from each other. Therefore, the layer containing quantum dots can sufficiently contain quantum dots and can be patterned.

According to the method of the first embodiment, the red light-emitting material layer 44 is formed on the red lower reversal resist layer 41 as illustrated in FIG. 8, and an unnecessary portion of the red light-emitting material layer 44 (that is, a portion that does not become the red light-emitting layer 35r) is removed together with the soluble portion 41B of the red lower reversal resist layer 41 as illustrated in FIG. 9. Therefore, mixing in of the light-emitting material of the red light-emitting layer 35r as a residue in a region other than the formation region of the red light-emitting layer 35r can be reduced. Similarly, mixing in of the light-emitting material of the green light-emitting layer 35g as a residue in a region other than the formation region of the green light-emitting layer 35g can be reduced. By reducing such mixing in, color mixing between the subpixels (light-emitting elements) can be reduced.

Further, according to the method of the first embodiment, the red light-emitting material layer 44 is further formed on the entire surface between the red lower reversal resist layer 41 and the red upper positive resist layer 45. The red light-emitting layer 35r is then formed by patterning the red light-emitting material layer 44 using a photoresist technique. Therefore, even in a case in which the red light-emitting material layer 44 is formed by applying a solution containing a red light-emitting material over the entire surface and then volatilizing the solvent from the solution, unevenness due to surface tension and a coffee ring effect do not occur in the red light-emitting layer 35r. As a result, the red light-emitting layer 35r can be formed in a flat and uniform manner. The same applies to the green light-emitting layer 35g and the blue light-emitting layer 35b.

According to the method of the first embodiment, the blue light-emitting material layer 64 is formed on the soluble portions 45C and 55C of the red upper positive resist layer 45 and the green upper positive resist layer 55 as illustrated in FIG. 16, and after unnecessary portions of the blue light-emitting material layer 64 (that is, portions that do not become the blue light-emitting layer 35b) have been removed as illustrated in FIG. 17, the soluble portions 45C and 55C of the red upper positive resist layer 45 and the green upper positive resist layer 55 are removed as illustrated in FIG. 19. Therefore, mixing in of the light-emitting material of the blue light-emitting layer 35b as a residue into regions of the red subpixel Pr and the green subpixel Pg can be reduced.

According to the method of the first embodiment, following the formation of red light-emitting layer 35r, the insoluble portion 41A of the red lower reversal resist layer 41 is converted through exposure and reversal firing to the re-insoluble portion 41D that is insoluble in the developing solution. The re-insoluble portion 41D remains insoluble in the developing solution even if further exposed or fired. Therefore, removal of the red light-emitting layer 35r by the developing solution in a subsequent step can be reduced. Similarly, removal of the green light-emitting layer 35g by the developing solution can also be reduced. Therefore, the thicknesses of the red light-emitting layer 35r, the green light-emitting layer 35g, and the blue light-emitting layer 35b can be easily controlled.

According to the method of the first embodiment, the soluble portion 45C of the red upper positive resist layer 45 is removed as illustrated in FIG. 19. Therefore, in the display device 2, the red upper positive resist layer 45 or a resin layer derived from the red upper positive resist layer 45 is not present on the red light-emitting layer 35r. Accordingly, the luminous efficiency of the red subpixel Pr can be improved. Similarly, the luminous efficiencies of the green subpixel Pg and the blue subpixel Pb can be improved.

In addition, since the soluble portion 45C of the red upper positive resist layer 45 is removed, the luminous efficiency of the red subpixel Pr is not affected even if the thickness of the red upper positive resist layer 45 is increased. Therefore, the thickness of the red upper positive resist layer 45 can be sufficiently increased such that the red light-emitting layer 35r is not damaged or thinned in a period from when the red upper positive resist layer 45 is formed until the soluble portion 45C of the red upper positive resist layer 45 is removed. Similarly, the thicknesses of the green upper positive resist layer 55 and the blue upper positive resist layer 65 can be sufficiently increased. Therefore, the thicknesses of the red light-emitting layer 35r, the green light-emitting layer 35g, and the blue light-emitting layer 35b can be easily controlled.

According to the method of the first embodiment, the red light-emitting layer 35r and the green light-emitting layer 35g each adhere to the substrate via the re-insoluble portions 41D and 51D of the red lower reversal resist layer 41 and the green lower reversal resist layer 51 in the step of developing using a strong developing solution. For this reason, detachment of the red light-emitting layer 35r and the green light-emitting layer 35g from the substrate during the manufacturing process can be reduced.

According to the method of the first embodiment, the main firing for thermally curing the red lower reversal resist layer 41 and the green lower reversal resist layer 51 can be implemented once as illustrated in FIG. 5. Alternatively, the main firing may optionally be not implemented. Therefore, chemical or mechanical damage caused by heating or temperature changes due to main firing can be reduced.

### Second Embodiment

Another embodiment of the disclosure will be described below. Note that, for convenience of description, members having the same functions as those of the members described in the above-described embodiment will be denoted by the same reference numerals and signs, and the description thereof will not be repeated.

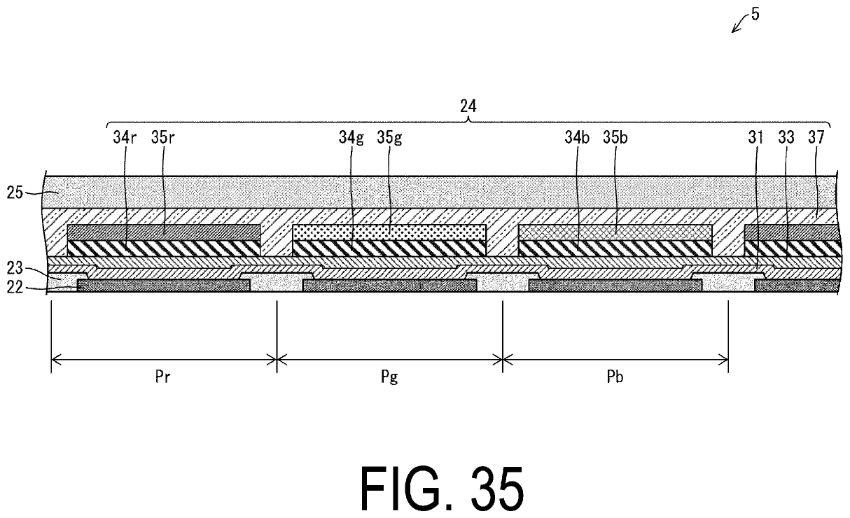

FIG. 35 is a schematic cross-sectional view illustrating an example of a configuration of the light-emitting element layer 5 in the display device 2 according to a second embodiment.

The example of the light-emitting element layer 5 according to the second embodiment includes a blue lower resin layer 34b between the hole transport layer 33 and the blue light-emitting layer 35b, and thereby differs from the above-described example of the light-emitting element layer 5 according to the first embodiment. In this case, the red lower resin layer 34r, the green lower resin layer 34g, and the blue lower resin layer 34b are collectively referred to as a “lower resin layer 34”. In other words, the light-emitting element layer 5 according to the second embodiment contains the lower resin layer 34 below all of the light-emitting layers 35, and thereby differs from the above-described light-emitting element layer 5 according to the first embodiment.

### Manufacturing Method

The configuration according to the second embodiment can be realized by executing the process P1 described in FIG. 6 in all of the steps of forming the light-emitting layers.

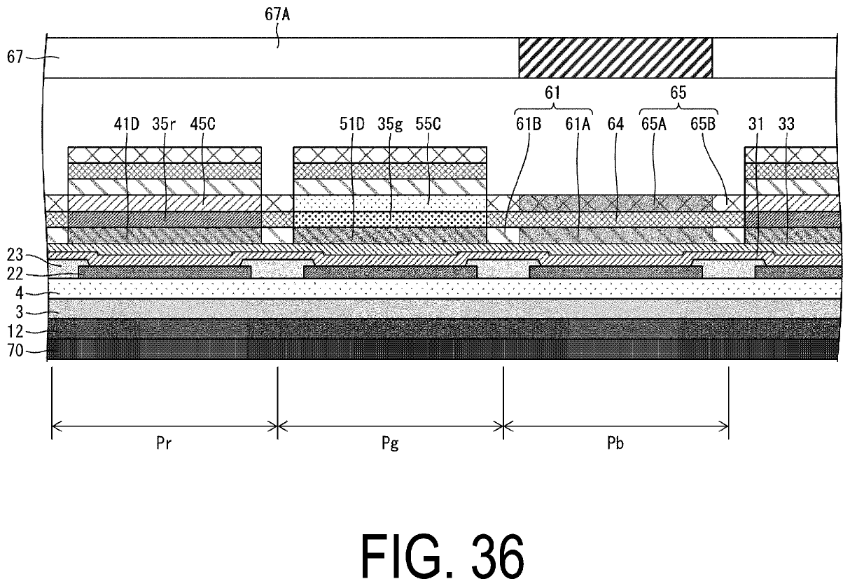

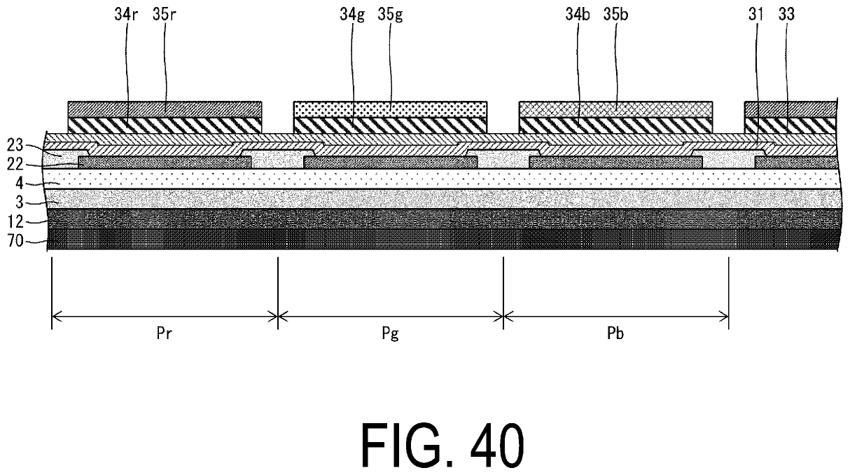

Hereinafter, with reference to FIGS. 36 to 40, an example of a step (step S4, light-emitting element formation step) of forming, on a substrate, the example of the light-emitting element layer 5 illustrated in FIG. 35 will be described in detail.

FIGS. 36 to 40 are each a schematic cross-sectional view illustrating an example of a step (step S4) of forming, on a substrate, the example of the light-emitting element layer 5 illustrated in FIG. 35.

First, similar to the first embodiment described above, the flow described in FIG. 5 is implemented up to the step (step S26) of implementing the process including the formation of the green light-emitting layer 35g.

### Process Including Formation of Blue Light-Emitting Layer

Next, as illustrated in FIG. 6 and FIG. 36, a process that includes formation of the blue light-emitting layer 35b is carried out (step S27). In step S27, the process P1 described in FIG. 6 is executed.

That is, first, as illustrated in FIGS. 6 and 36, a blue lower reversal resist layer 61 (third reversal resist) is formed over the entire surface by applying a reversal resist material over the entire surface of the hole transport layer 33 and the soluble portions 45C and 55C of the red upper positive resist layer 45 and the green upper positive resist layer 55 (step S41, part of the third light-emitting layer formation step). Subsequently, the blue light-emitting material layer 64 and the blue upper positive resist layer 65 are formed (steps S42 and S43, part of the third light-emitting layer formation step). In this manner, a layered body (third layered body) is formed including the blue lower reversal resist layer 61, the blue light-emitting material layer 64, and the blue upper positive resist layer 65 in this order from the substrate side.

Next, the layered body described above is subjected to a first exposure with ultraviolet light using a blue first mask 67 (step S44, part of the third light-emitting layer formation step). As a result, the portions of the blue lower reversal resist layer 61 and the blue upper positive resist layer 65 that do not overlap the blue light-emitting layer 35b do not undergo the photochemical reaction, and thus remain as insoluble portions 61A and 65A that are insoluble in the developing solution. On the other hand, the other portions are converted through the photochemical reaction to the soluble portions 61B and 65B that are soluble in the developing solution.

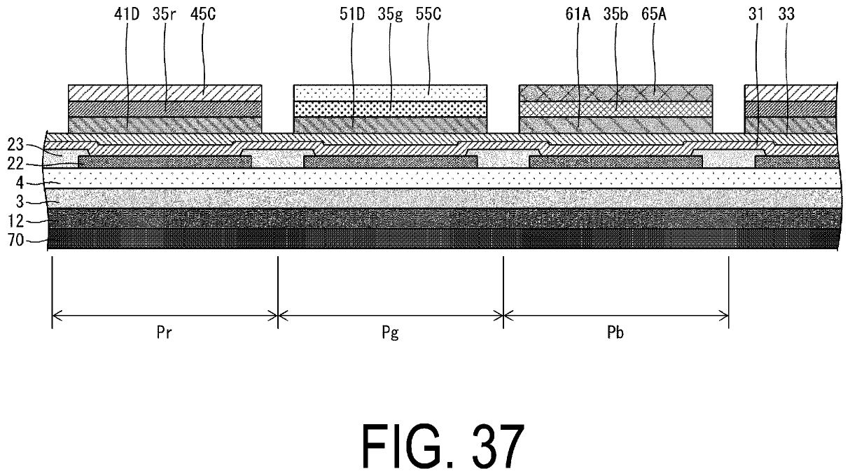

Next, as illustrated in FIGS. 6 and 37, development is carried out using a strong developing solution (step S45, part of the third light-emitting layer formation step). As a result, the soluble portions 61B and 65B of the blue lower reversal resist layer 61 and the blue upper positive resist layer 65 and the portion of the blue light-emitting material layer 64 therebetween are removed. On the other hand, the insoluble portions 61A and 65A of the blue lower reversal resist layer 61 and the blue upper positive resist layer 65 and the portion of the blue light-emitting material layer 64 therebetween remain. The remaining portion of the blue light-emitting material layer 64 becomes the blue light-emitting layer 35b.

By using the photolithography technique and re-insolubilization of the reversal resist in this manner, the layered body described above is patterned, and as a result, the blue light-emitting layer 35b is formed.

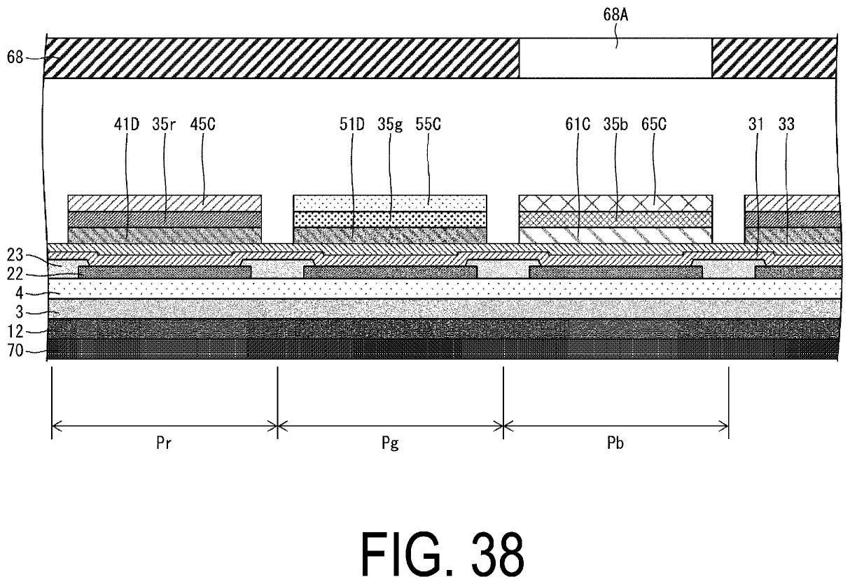

Next, as illustrated in FIGS. 6 and 38, the above-described layered body subjected to patterning is subjected to a second exposure with ultraviolet light using a blue second mask 68 (step S46, part of the third re-insolubilization step). As a result, the insoluble portions 61A and 65A of the blue lower reversal resist layer 61 and the blue upper positive resist layer 65 are converted through a photochemical reaction to soluble portions 61C and 65C that are soluble in the developing solution.

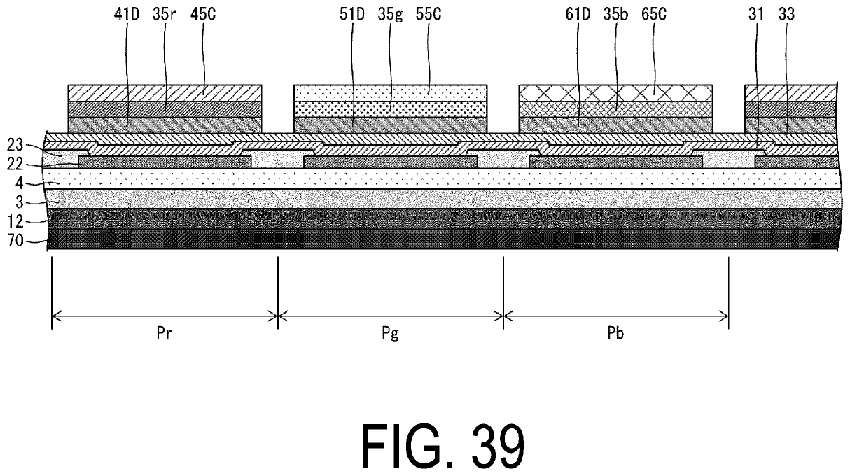

Next, as illustrated in FIGS. 6 and 39, the above-described layered body that was patterned is subjected to reversal firing (step S47, part of the third re-insolubilization step). As a result, through decarboxylation, the soluble portion 61C of the blue lower reversal resist layer 61 becomes a re-insoluble portion 61D that is insoluble in the developing solution. On the other hand, the soluble portion 65C of the blue upper positive resist layer 65 remains as the soluble portion 65C.

In step S27, as described above, the blue light-emitting layer 35b is formed in a state of being sandwiched and protected between the re-insoluble portion 61D of the blue lower reversal resist layer 61 and the soluble portion 65C of the blue upper positive resist layer 65.

Subsequently, similar to the first embodiment described above, the step of carrying out weak development (step S28 in FIG. 5, positive resist removal step) and the subsequent steps are implemented. In this manner, the light-emitting element layer 5 illustrated in FIG. 30 is formed.

### Action and Effects

According to the method of the second embodiment, the blue light-emitting material layer 64 is formed on the blue lower reversal resist layer 61 as illustrated in FIG. 36, and an unnecessary portion of the blue light-emitting material layer 64 (that is, a portion that does not become the blue light-emitting layer 35b) is removed together with the soluble portion 61B of the blue lower reversal resist layer 61 as illustrated in FIG. 37.

Therefore, according to the method of the second embodiment, mixing in of the light-emitting material of the blue light-emitting layer 35b as a residue in a region other than the formation region of the blue light-emitting layer 35b can be reduced in comparison to the method of the first embodiment described above. Specifically, mixing of the light-emitting material of the blue light-emitting layer 35b as a residue into the side surfaces of the red light-emitting layer 35r and the green light-emitting layer 35g, the side surfaces of the red lower resin layer 34r and the green lower resin layer 34g, and the upper surface of the hole transport layer 33 can be reduced.

According to the method of the second embodiment, the blue light-emitting layer 35b adheres to the substrate via the re-insoluble portion 61D of the blue lower reversal resist layer 61 in the step of developing using a strong developing solution. Therefore, detachment of the blue light-emitting layer 35b from the substrate during the manufacturing process can be further reduced.

### Third Embodiment

Another embodiment of the disclosure will be described below. Note that, for convenience of description, members having the same functions as those of the members described in the above-described embodiment will be denoted by the same reference numerals and signs, and the description thereof will not be repeated.

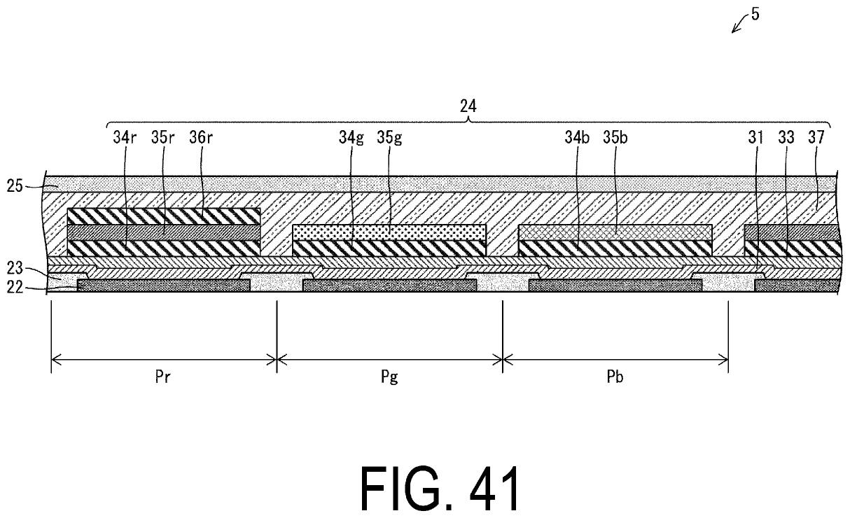

FIG. 41 is a schematic cross-sectional view illustrating an example of a configuration of the light-emitting element layer 5 in the display device 2 according to a third embodiment.

An example of the light-emitting element layer 5 according to the third embodiment includes the lower resin layer 34 below all of the light-emitting layers 35, and includes the red upper resin layer 36r between the red light-emitting layer 35r and the electron transport layer 37, and thereby the example of the light-emitting element layer 5 according to the third embodiment differs from the example of the light-emitting element layer 5 according to the first embodiment described above.

### Manufacturing Method 1

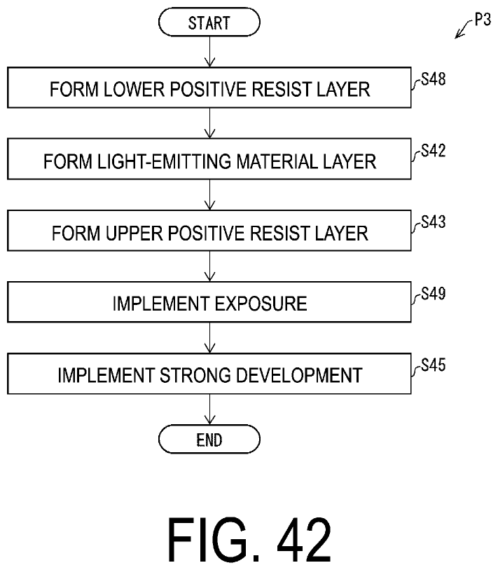

Hereinafter, with reference to FIGS. 42 to 44, an example of a step (step S4, light-emitting element formation step) of forming, on a substrate, the example of the light-emitting element layer 5 illustrated in FIG. 41 will be described in detail.

The configuration according to the second embodiment can be realized by implementing step S25 last among the steps S25 to S27 described in FIG. 4 and executing, in step S25, the process P3 described in FIG. 42. Note that the process P1 described in FIG. 6 is executed in steps S26 and S27.

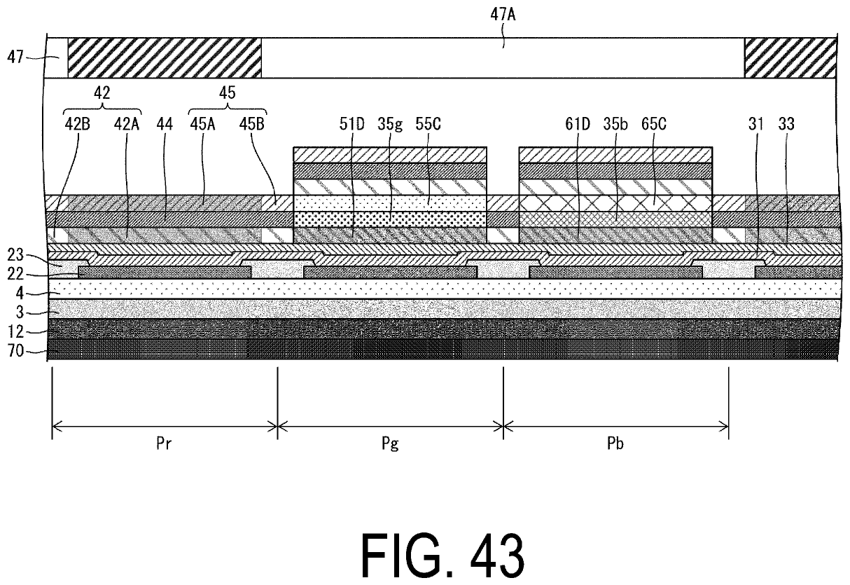

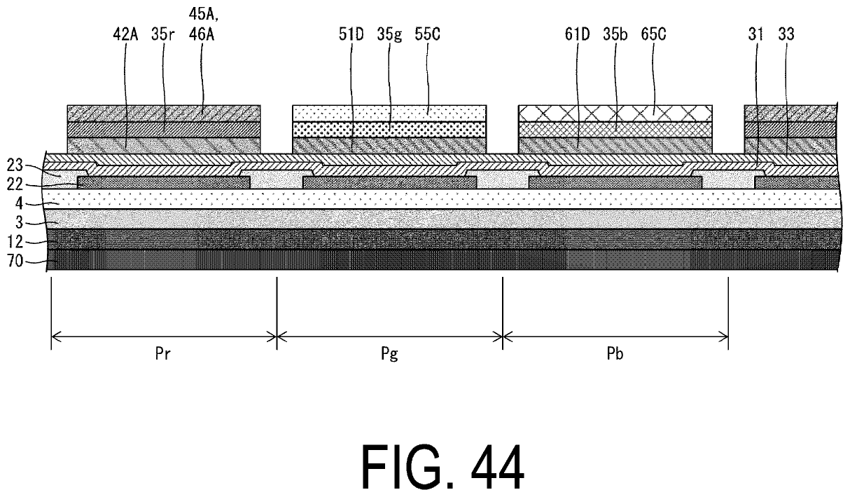

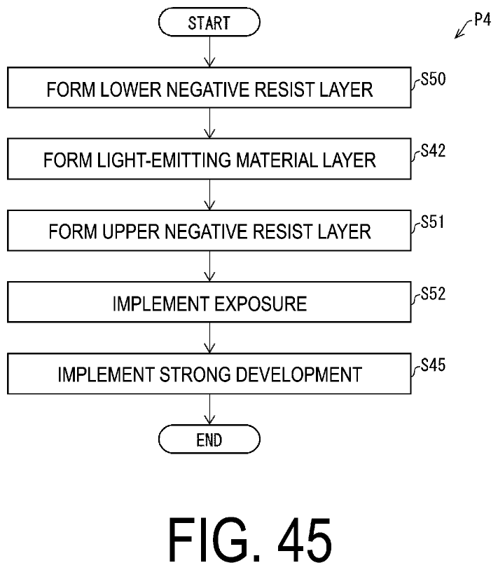

FIG. 42 is a schematic flowchart describing a process (process P3) that is executed to form the light-emitting element layer 5 illustrated in FIG. 41. FIG. 43 is a schematic cross-sectional view illustrating the process P3 described in FIG. 42. FIG. 44 is a schematic cross-sectional view illustrating the process P3 described in FIG. 42 and a process P4 described in FIG. 45 described below.

First, similar to a modified example of the first embodiment described above, the manufacturing flow is implemented as far as the step of implementing the process including the formation of the blue light-emitting layer 35b (step S27, first light-emitting layer formation step) and the step of implementing the process including the formation of the green light-emitting layer 35g (step S26, second light-emitting layer formation step).

Next, a step (step S25) of implementing a process including the formation of the red light-emitting layer 35r is carried out. Here, as illustrated in FIGS. 42 and 43, the red lower positive resist layer 42 is formed over the entire surface by applying a positive resist material onto the entire surface of the hole transport layer 33 (step S48, a part of the third light-emitting layer formation step). Subsequently, the red light-emitting material layer 44 and the red upper positive resist layer 45 are formed on the entire surface (steps S42 and S43, a part of the third light-emitting layer formation step).

In this manner, a layered body (third layered body) is formed with the red light-emitting material layer 44 (third light-emitting material layer) layered between the red lower positive resist layer 42 and the red upper positive resist layer 45 (two layers of positive resist). At this time, the red lower positive resist layer 42 and the red upper positive resist layer 45 are both insoluble in the developing solution.

Next, the layered body described above is exposed to ultraviolet light using a red first mask 47 (step S49, part of the third light-emitting layer formation step). In this process P3, unlike the process P1 (see FIG. 6) and the process P2 (see FIG. 7), exposure is implemented only once.

As a result, the portions of the red lower positive resist layer 42 and the red upper positive resist layer 45 that overlap the red light-emitting layer 35r remain as insoluble portions 42A and 45A that are insoluble in the developing solution without undergoing a photochemical reaction. On the other hand, the other portions are converted through the photochemical reaction to the soluble portions 42B and 45B that are soluble in the developing solution.

Next, as illustrated in FIGS. 42 and 44, strong developing is carried out (step S45, a part of the third light-emitting layer formation step). As a result, the soluble portions 42B and 45B of the red lower positive resist layer 42 and the red upper positive resist layer 45 and the portion of the red light-emitting material layer 44 therebetween are removed. On the other hand, the insoluble portions 42A and 45A of the red lower positive resist layer 42 and the red upper positive resist layer 45 and the portion of the red light-emitting material layer 44 therebetween remain. The remaining portion of the red light-emitting material layer 44 becomes the red light-emitting layer 35r.

In Step S25, as described above, the red light-emitting layer 35r is formed in a state of being sandwiched and protected between the insoluble portions 42A and 45A of the red lower positive resist layer 42 and the red upper positive resist layer 45.

Subsequently, similar to the first embodiment described above, the step of carrying out weak development (step S28 in FIG. 5) and the subsequent steps are implemented. The insoluble portions 42A and 45A of the red lower positive resist layer 42 and the red upper positive resist layer 45 become the red lower resin layer 34r and the red upper resin layer 36r, respectively, as they are or after passing through a main firing. In this manner, the light-emitting element layer 5 illustrated in FIG. 41 is formed.

Through this method as well, mixing in of the light-emitting materials of each of the light-emitting layers 35 as residues in regions other than the formation regions of the light-emitting layers 35 can be reduced.

### Manufacturing Method 2

Hereinafter, with reference to FIGS. 44 to 46, another example of a step (step S4, light-emitting element formation step) of forming, on a substrate, the example of the light-emitting element layer 5 illustrated in FIG. 41 will be described in detail.

The configuration according to the second embodiment can be realized by executing the process P4 described in FIG. 45 in the step S25 among the steps S25 to S27 described in FIG. 5. Here, the process P1 described in FIG. 6 is executed in step S26 and step S27. In addition, the process P4 uses a negative resist material, and therefore the order in which steps S25 to S27 (see FIG. 5) are carried out can be changed.

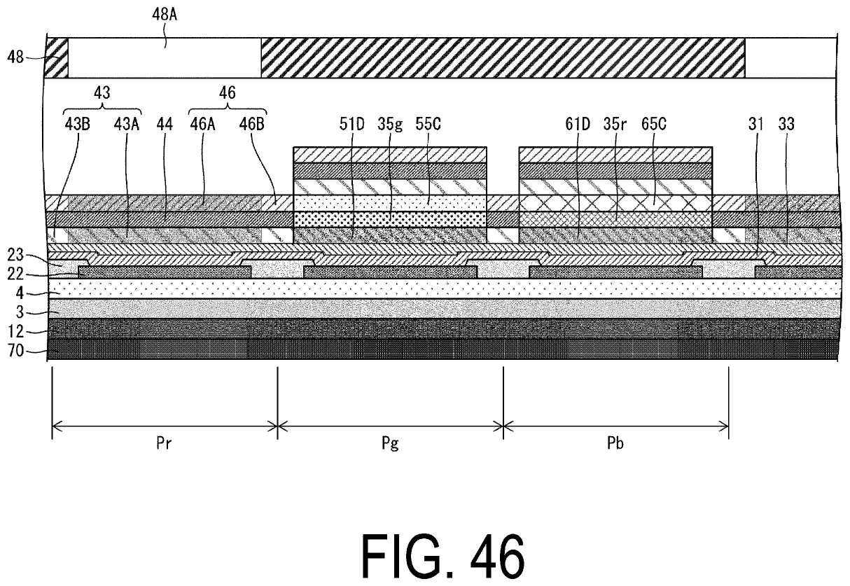

FIG. 45 is a schematic flowchart describing another process (process P4) that is executed to form the light-emitting element layer 5 illustrated in FIG. 41. FIG. 46 is a schematic cross-sectional view illustrating the process P4 described in FIG. 45.

First, similar to a modified example of the first embodiment described above, the manufacturing flow is implemented as far as the step of implementing the process including the formation of the blue light-emitting layer 35b (step S27, first light-emitting layer formation step) and the step of implementing the process including the formation of the green light-emitting layer 35g (step S26, second light-emitting layer formation step).

Next, a step (step S25) of implementing a process including the formation of the red light-emitting layer 35r is carried out. Here, as indicated in FIGS. 45 and 46, a red lower negative resist layer 43 is formed over the entire surface by applying a negative resist material onto the entire surface of the hole transport layer 33 (step S50, a part of the third light-emitting layer formation step). Subsequently, the red light-emitting material layer 44 is formed on the entire surface (step S42, a part of the third light-emitting layer formation step). Subsequently, a red upper negative resist layer 46 is formed over the entire surface by applying a negative resist material onto the entire surface of the red light-emitting material layer 44 (Step S51, a part of the third light-emitting layer formation step). As used herein, the term “negative resist material” means a material that includes a negative-type photoresist.

In this manner, a layered body (third layered body) is formed with the red light-emitting material layer 44 (third light-emitting material layer) layered between the red lower negative resist layer 43 and the red upper negative resist layer 46 (two layers of negative resist). At this time, the red lower negative resist layer 43 and the red upper negative resist layer 46 are both soluble in the developing solution.

Next, the above-described layered body is exposed to ultraviolet light using the red second mask 48 (step S52, a part of the third light-emitting layer formation step). In this process P4, unlike the process P1 (see FIG. 6) and the process P2 (see FIG. 7), exposure is implemented only once.

As a result, the portions of the red lower negative resist layer 43 and the red upper negative resist layer 46 that overlap the red light-emitting layer 35r undergo a photochemical reaction and become insoluble portions 43A and 46A that are insoluble in the developing solution. On the other hand, the other portions remain as soluble portions 43B and 46B that are soluble in the developing solution without undergoing a photochemical reaction.

Next, as illustrated in FIGS. 45 and 44, strong developing is carried out (step S45, a part of the third light-emitting layer formation step). As a result, the soluble portions 43B and 46B of the red lower negative resist layer 43 and the red upper negative resist layer 46 and the portion of the red light-emitting material layer 44 therebetween are removed. On the other hand, the insoluble portions 43A and 46A of the red lower negative resist layer 43 and the red upper negative resist layer 46 and the portion of the red light-emitting material layer 44 therebetween remain. The remaining portion of the red light-emitting material layer 44 becomes the red light-emitting layer 35r.

In Step S25, as described above, the red light-emitting layer 35r is formed in a state of being sandwiched and protected between the insoluble portions 43A and 46A of the red lower negative resist layer 43 and the red upper negative resist layer 46.

Subsequently, similar to the first embodiment described above, the step of carrying out weak development (step S28 in FIG. 5) and the subsequent steps are implemented. The insoluble portions 43A and 46A of the red lower negative resist layer 43 and the red upper negative resist layer 46 become the red lower resin layer 34r and the red upper resin layer 36r, respectively, as they are or after passing through a main firing. In this manner, the light-emitting element layer 5 illustrated in FIG. 41 is formed.

Through this method as well, mixing in of the light-emitting materials of each of the light-emitting layers 35 as a residue in regions other than the formation regions of the light-emitting layers 35 can be reduced.

### Action and Effects

According to the method of the third embodiment, mixing in of the light-emitting material of each light-emitting layer as residue in a formation region of another light-emitting layer can be further reduced in comparison to the method according to the first embodiment described above.

### Fourth Embodiment

Another embodiment of the disclosure will be described below. Note that, for convenience of description, members having the same functions as those of the members described in the above-described embodiment will be denoted by the same reference numerals and signs, and the description thereof will not be repeated.

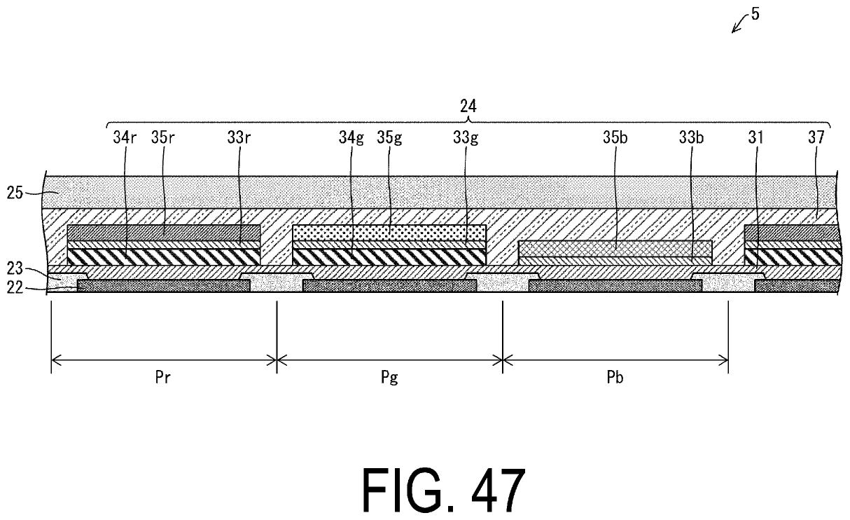

FIG. 47 is a schematic cross-sectional view illustrating an example of a configuration of the light-emitting element layer 5 in the display device 2 according to a fourth embodiment.

The example of the light-emitting element layer 5 according to the fourth embodiment includes, in place of the hole transport layer 33 formed on the entire surface, a red hole transport layer 33r, a green hole transport layer 33g, and a blue hole transport layer 33b, each of which is patterned, and thereby the example of the light-emitting element layer 5 according to the fourth embodiment differs from the example of the light-emitting element layer 5 according to the first embodiment described above.

### Manufacturing Method

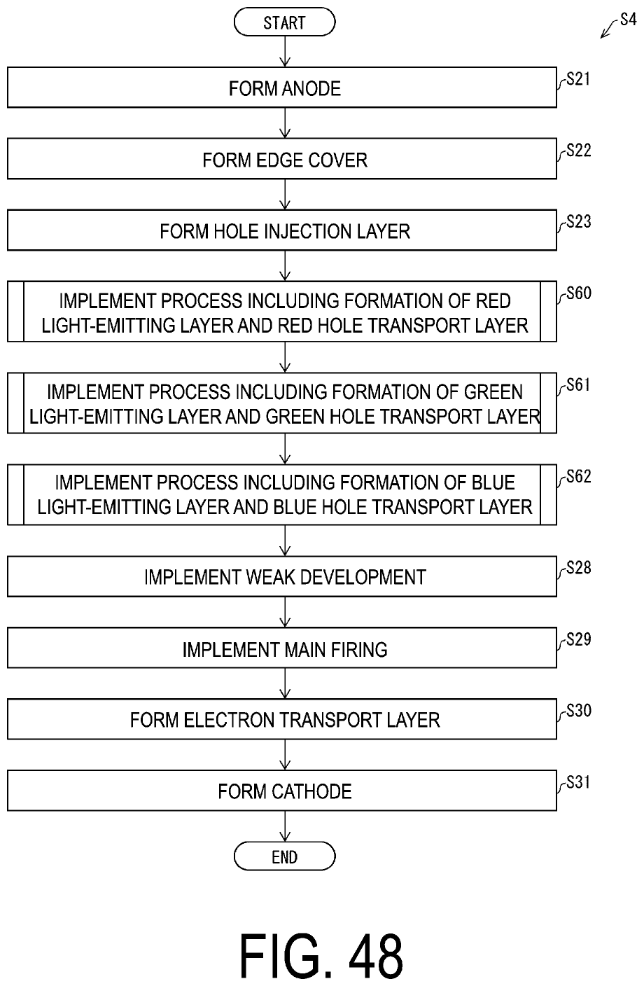

Hereinafter, with reference to FIGS. 48 to 53, an example of a step (step S4, light-emitting element formation step) of forming, on a substrate, the example of the light-emitting element layer 5 illustrated in FIG. 47 will be described in detail.

FIGS. 48 to 53 are each a cross-sectional view illustrating an example of a step (step S4, light-emitting element formation step) of forming, on a substrate, the example of the light-emitting element layer 5 illustrated in FIG. 47.

First, the manufacturing flow illustrated in FIG. 46 is implemented in the same manner as in the above-described first embodiment up to the step (step S23) of forming a hole injection layer.

### Process Including Formation of Red Light-Emitting Layer and Red Hole Transport Layer

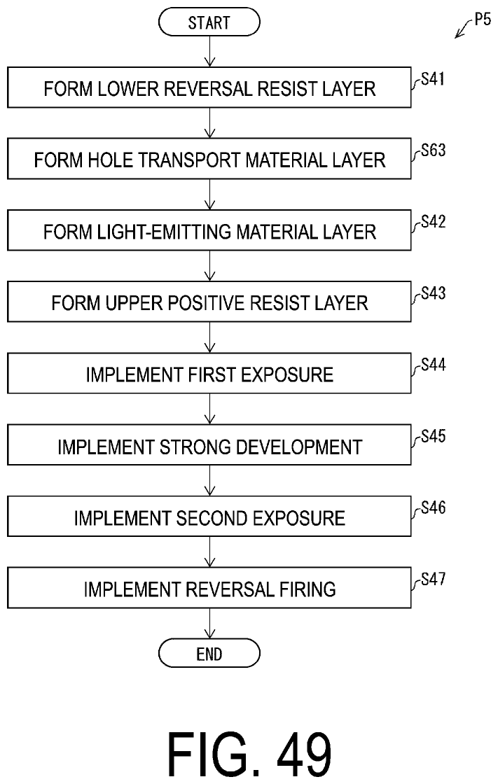

Next, as described in FIG. 48, a process including formation of the red light-emitting layer 35r and the red hole transport layer 33r is carried out (step S60). In step S60, the process P5 described in FIG. 49 is executed. The process P5 described in FIG. 49 includes a step (step S63) of forming a hole transport material layer, and thereby differs from the process P1 described in FIG. 6.

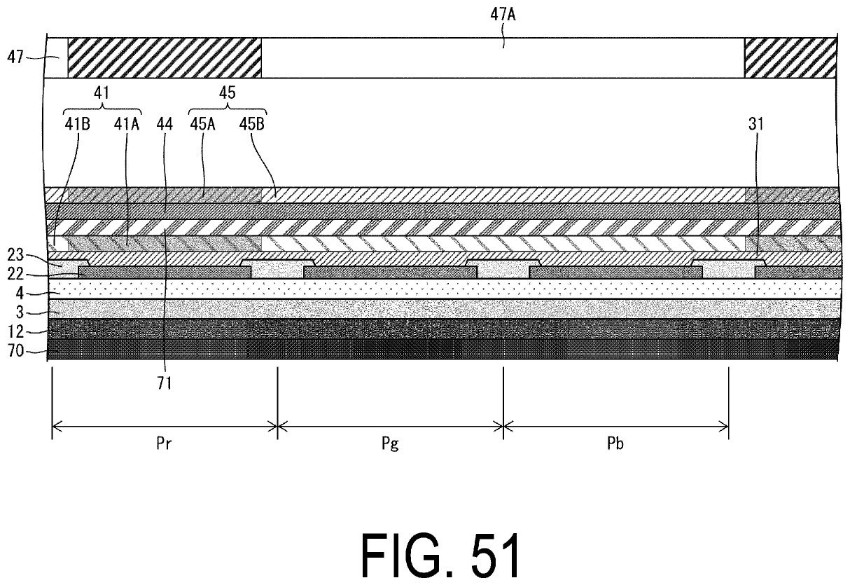

That is, as illustrated in FIGS. 49 and 51, the red lower reversal resist layer 41 is first formed on the entire surface (step S41). Subsequently, a red hole transport material layer 71 (carrier transport material layer) is formed on the entire surface of the red lower reversal resist layer 41 by vapor deposition of a hole transport material (material of the carrier transport layer) onto the entire surface of the red lower reversal resist layer 41 or by applying a material containing a hole transport material onto the entire surface thereof (step S63). Subsequently, the red light-emitting material layer 44 and the red upper positive resist layer 45 are formed on the entire surface (steps S42 and S43).

In this manner, a layered body (first layered body) is formed including the red lower reversal resist layer 41, the red hole transport material layer 71, the red light-emitting material layer 44, and the red upper positive resist layer 45 in this order from the substrate side.

Next, as illustrated in FIG. 49, steps S44 and S45 are implemented in the same manner as in the first embodiment described above. As a result, the red hole transport material layer 71 is patterned together with the red light-emitting material layer 44, and the remaining portion of the red hole transport material layer 71 becomes the red hole transport layer 33r.

Subsequently, steps S46 and S47 are implemented in the same manner as in the first embodiment described above. As a result, the red light-emitting layer 35r and the red hole transport layer 33r are formed in a state of being sandwiched and protected between the re-insoluble portion 41D of the red lower reversal resist layer 41 and the soluble portion 45C of the red upper positive resist layer 45.

### Process Including Formation of Green Light-Emitting Layer and Green Hole Transport Layer

Next, as described in FIG. 48, a process including formation of the green light-emitting layer 35g and the green hole transport layer 33g is carried out (step S61). In step S61, the process P5 described in FIG. 49 is executed.

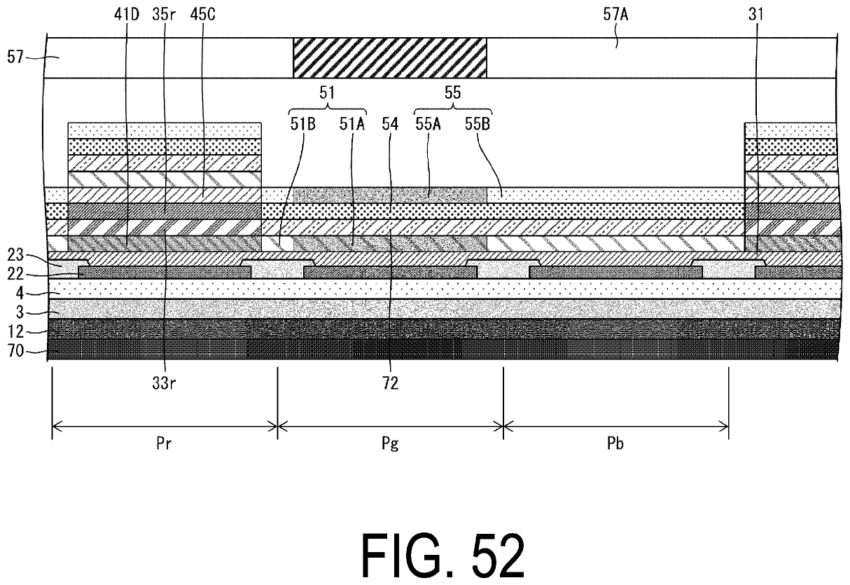

That is, as illustrated in FIGS. 49 and 52, first, the green lower reversal resist layer 51 is formed on the entire surface (step S41). Subsequently, a hole transport material is vapor deposited on the entire surface of the green lower reversal resist layer 51, or a material containing a hole transport material is applied on the entire surface of the green lower reversal resist layer 51, and thereby a green hole transport material layer 72 is formed on the entire surface of the green lower reversal resist layer 51 (step S63). Subsequently, the green light-emitting material layer 54 and the green upper positive resist layer 55 are formed on the entire surface (steps S42 and S43).

In this manner, a layered body including the green lower reversal resist layer 51, the green hole transport material layer 72, the green light-emitting material layer 54, and the green upper positive resist layer 55 in this order from the substrate side is formed.

Next, as illustrated in FIG. 49, steps S44 and S45 are implemented in the same manner as in the first embodiment described above. Through this, the green hole transport material layer 72 is patterned together with the green light-emitting material layer 54, and the remaining portion of the green hole transport material layer 72 becomes the green hole transport layer 33g.

Subsequently, steps S46 and S47 are implemented in the same manner as in the first embodiment described above. As a result, the green light-emitting layer 35g and the green hole transport layer 33g are formed in a state of being sandwiched and protected between the re-insoluble portion 51D of the green lower reversal resist layer 51 and the soluble portion 55C of the green upper positive resist layer 55.

### Process Including Formation of Blue Light-Emitting Layer and Blue Hole Transport Layer

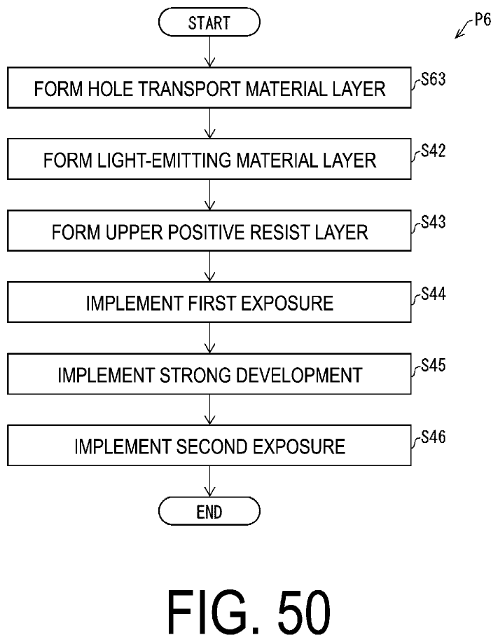

Next, as described in FIG. 48, a process including formation of the blue light-emitting layer 35b and the blue hole transport layer 33b is carried out (step S62). In step S62, a process P6 described in FIG. 50 is executed. The process P6 described in FIG. 50 includes a step (step S62) of forming a hole transport material layer, and thereby differs from the process P2 described in FIG. 7.

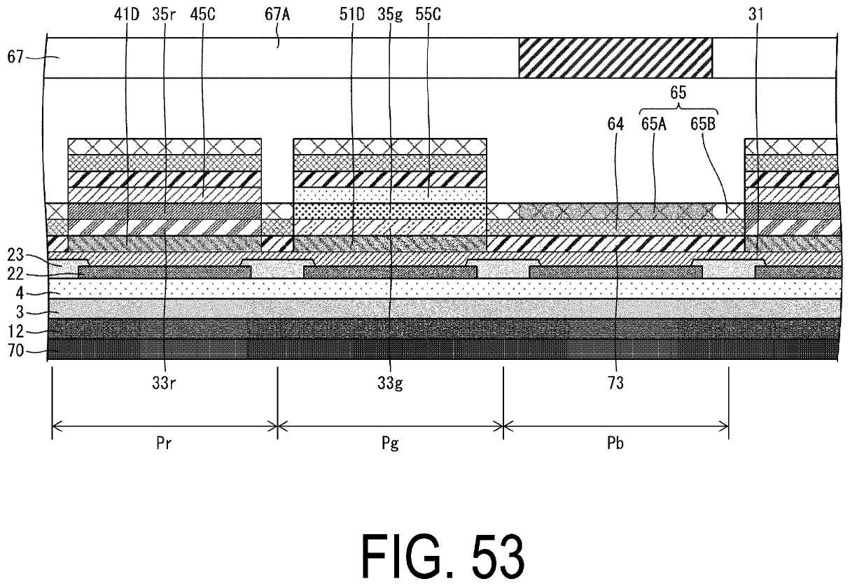

That is, as illustrated in FIGS. 50 and 53, first, a blue hole transport material layer 73 is formed over the entire surfaces of the hole injection layer 31 and the soluble portions 45C and 55C of the red upper positive resist layer 45 and the green upper positive resist layer 55 by vapor deposition of a hole transport material on the entire surfaces thereof, or by applying a material containing a hole transport material to the entire surfaces thereof (step S63). Subsequently, the blue light-emitting material layer 64 and the blue upper positive resist layer 65 are formed on the entire surfaces (steps S42 and S43).

In this manner, a layered body including the blue hole transport material layer 73, the blue light-emitting material layer 64, and the blue upper positive resist layer 65 in this order from the substrate side is formed.

Next, as illustrated in FIG. 50, steps S44 and S45 are implemented in the same manner as in the above-described first embodiment. Through this, the blue hole transport material layer 73 is patterned together with the blue light-emitting material layer 64, and the remaining portion of the blue hole transport material layer 73 becomes the blue hole transport layer 33b.

Subsequently, step S46 is carried out in the same manner as in the first embodiment described above. As a result, the blue light-emitting layer 35b and the blue hole transport layer 33b are formed in a state of being covered and protected under the soluble portion 65C of the blue upper positive resist layer 65.

Subsequently, similar to the first embodiment described above, the step of carrying out weak development (step S28 in FIG. 5) and the subsequent steps are implemented. In this manner, the light-emitting element layer 5 illustrated in FIG. 47 is formed.

### Action and Effects

According to the method of the fourth embodiment, the red hole transport layer 33r corresponding to the red light-emitting layer 35r can also be patterned together with the red light-emitting layer 35r. Therefore, a red hole transport layer 33r suitable for the red light-emitting layer can be formed. In addition, mixing in of the hole transport material of the red hole transport layer 33r as a residue in a region other than the formation region of the red hole transport layer 33r can be reduced. The same applies to the green hole transport layer 33g and the blue hole transport layer 33b.

The scope of the fourth embodiment is not limited thereto, and includes various modified examples, such as an example in which a layer other than the hole transport layer is patterned together with the light-emitting layer, an example in which a layer such as a hole transport layer is patterned together with the light-emitting layer in the second and third embodiments, and an example in which a layer such as a hole transport layer is patterned together with only one or several light-emitting layers among a plurality of light-emitting layers.

### Supplement

A method of manufacturing a light-emitting device according to a first aspect of the disclosure is a method of manufacturing a light-emitting device, the manufacturing method including a light-emitting element formation step in which a first light-emitting element including a first light-emitting layer is formed on a substrate, wherein the light-emitting element formation step includes a first light-emitting layer formation step of forming the first light-emitting layer by patterning a first layered body obtained by layering, in order from the substrate side, a first reversal resist, a first light-emitting material layer containing a light-emitting material of the first light-emitting layer, and a first positive resist.

A method of manufacturing a light-emitting device according to a second aspect of the disclosure is the method according to the first aspect, wherein the first light-emitting layer formation step preferably includes: a layered body formation step in which each layer of the first layered body is formed; a layered body exposure step in which, subsequent to the layered body formation step, a portion of the first layered body is exposed; and a development step in which subsequent to the layered body exposure step, the exposed portion of the first layered body is removed by removing the exposed first reversal resist.

A method of manufacturing a light-emitting device according to a third aspect of the disclosure is the method according to the first or second aspect, wherein the light-emitting element formation step preferably further includes, subsequent to the first light-emitting layer formation step, a first re-insolubilization step in which the first reversal resist overlapping the first light-emitting layer is solubilized and insolubilized.

A method of manufacturing a light-emitting device according to a fourth aspect of the disclosure is the method according to the third aspect, wherein the first re-insolubilization step preferably includes: a reversal resist exposure step in which the first reversal resist is exposed; and a heating step in which subsequent to the reversal resist exposure step, the exposed first reversal resist is heated.

A method of manufacturing a light-emitting device according to a fifth aspect of the disclosure is the method according to the third or fourth aspect, wherein preferably, in the light-emitting element formation step, a second light-emitting element including a second light-emitting layer having a material differing from that of the first light-emitting layer is further formed on the substrate, and the light-emitting element formation step further includes a second light-emitting layer formation step in which after the first re-insolubilization step, the second light-emitting layer is formed by patterning a second layered body obtained by layering, in order from the substrate side, a second reversal resist, a second light-emitting material layer including a light-emitting material of the second light-emitting layer, and a second positive resist.

A method of manufacturing a light-emitting device according to a sixth aspect of the disclosure is the method according to the fifth aspect, wherein the light-emitting element formation step preferably further includes a second re-insolubilization step in which subsequent to the second light-emitting layer formation step, the second reversal resist overlapping the second light-emitting layer is solubilized and insolubilized.

A method of manufacturing a light-emitting device according to a seventh aspect of the disclosure is the method according to the sixth aspect, wherein the light-emitting element formation step preferably further includes, subsequent to the second re-insolubilization step, a positive resist removal step in which the first positive resist and the second positive resist are removed from an upper layer of the first light-emitting layer and an upper layer of the second light-emitting layer, respectively.

A method of manufacturing a light-emitting device according to an eighth aspect of the disclosure is the method according to the sixth or seventh aspect, wherein preferably, in the light-emitting element formation step, a third light-emitting element containing a third light-emitting layer having a material differing from those of both the first light-emitting layer and the second light-emitting layer is further formed on the substrate, and the light-emitting element formation step further includes a third light-emitting layer formation step in which, after the second re-insolubilization step, the third light-emitting layer is formed by patterning a third layered body obtained by layering, in order from the substrate side, a third light-emitting material layer containing a light-emitting material of the third light-emitting layer, and a third positive resist.

A method of manufacturing a light-emitting device according to a ninth aspect of the disclosure is the method according to the sixth aspect, wherein preferably, in the light-emitting element formation step, a third light-emitting element containing a third light-emitting layer having a material differing from those of both the first light-emitting layer and the second light-emitting layer is further formed, and the light-emitting element formation step further includes, after the second re-insolubilization step, a third light-emitting layer formation step in which the third light-emitting layer is formed by patterning a third layered body obtained by layering, in order from the substrate side, a third reversal resist, a third light-emitting material layer containing a light-emitting material of the third light-emitting layer, and a third positive resist.

A method of manufacturing a light-emitting device according to a tenth aspect of the disclosure is the method according to the ninth aspect, wherein preferably, the light-emitting element formation step further includes, subsequent to the third light-emitting layer formation step, a third re-insolubilization step in which the third reversal resist overlapping the third light-emitting layer is solubilized and insolubilized.

A method of manufacturing a light-emitting device according to an eleventh aspect of the disclosure is the method according to the tenth aspect, wherein preferably, the light-emitting element formation step further includes, after the third re-insolubilization step, a positive resist removal step in which the first positive resist, the second positive resist, and the third positive resist are removed from upper layers of each of the first light-emitting layer, the second light-emitting layer, and the third light-emitting layer, respectively.

A method of manufacturing a light-emitting device according to a twelfth aspect of the disclosure is the method according to the sixth or seventh aspect, wherein preferably, in the light-emitting element formation step, a third light-emitting element containing a third light-emitting layer having a material differing from those of both the first light-emitting layer and the second light-emitting layer is further formed on the substrate, and the light-emitting element formation step includes, after the second re-insolubilization step, a third light-emitting layer formation step in which the third light-emitting layer is formed by patterning a third layered body obtained by layering, between two layers of a third positive resist, a third light-emitting material layer containing a light-emitting material of the third light-emitting layer.

A method of manufacturing a light-emitting device according to a thirteenth aspect of the disclosure is the method according to the sixth or seventh aspect, wherein preferably, in the light-emitting element formation step, a third light-emitting element containing a third light-emitting layer having a material differing from those of both the first light-emitting layer and the second light-emitting layer is further formed on the substrate, and the light-emitting element formation step includes a third light-emitting layer formation step in which the third light-emitting layer is formed by patterning a third layered body obtained by layering, between two layers of a negative resist, a third light-emitting material layer containing a light-emitting material of the third light-emitting layer.

A method of manufacturing a light-emitting device according to a fourteenth aspect of the disclosure is the method according to any one of the first to thirteenth aspects, wherein preferably, the first light-emitting element further includes a lower layer electrode between the substrate and the first light-emitting layer, and a carrier transport layer between the lower layer electrode and the first light-emitting layer, the first layered body further includes, layered between the first reversal resist and the first light-emitting material layer, a carrier transport material layer containing a material of the carrier transport layer, and in the first light-emitting layer formation step, the carrier transport material layer is further patterned to form the carrier transport layer.

A light-emitting device according to a fifteenth aspect of the disclosure is configured including: a substrate; and a first light-emitting element on the substrate, the first light-emitting element including a first lower layer electrode, a first light-emitting layer, and a first upper layer electrode layered in this order from the substrate side, wherein the first light-emitting element further includes a photosensitive resin layer between the first lower layer electrode and the first light-emitting layer, and the photosensitive resin layer includes at least one selected from the group consisting of compounds represented by the following structural formulas (1) to (3).

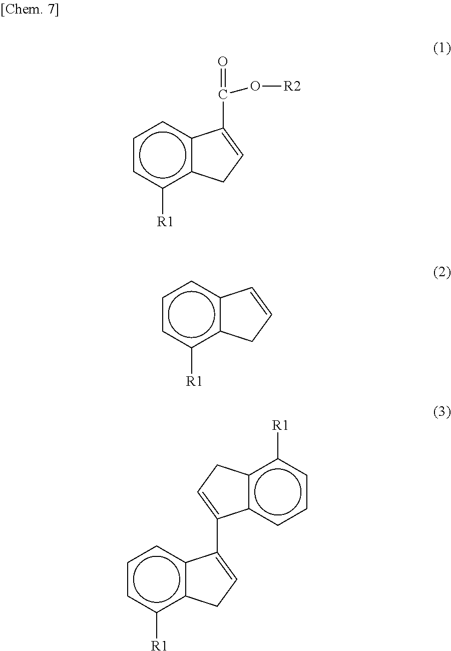

Here, R1 and R2 each independently represent a substituted or unsubstituted hydrocarbon group.

A light-emitting device according to a sixteenth aspect of the disclosure is the light-emitting device according to the fifteenth aspect, wherein preferably, the photosensitive resin layer further includes at least one selected from the group consisting of aromatic hydrocarbons having a hydroxyl group, 1-hydroxyethyl-2-alkylimidazoline, and shellac.

A light-emitting device according to a seventeenth aspect of the disclosure is the light-emitting device according to the fifteenth or sixteenth aspect, wherein preferably, the first light-emitting layer includes quantum dots as a light-emitting material.

A light-emitting device according to an eighteenth aspect of the disclosure is the light-emitting device according to any one of the fifteenth to seventeenth aspects, wherein preferably, the first light-emitting layer contains a positive-type photosensitive resin.

A light-emitting device according to a nineteenth aspect of the disclosure is the light-emitting device according to any one of the fifteenth to eighteenth aspects, wherein preferably, the first lower layer electrode is a cathode, the first upper layer electrode is an anode, the first light-emitting element further includes an electron transport layer between the first lower layer electrode and the photosensitive resin layer, and the electron affinity of the photosensitive resin layer is smaller than the electron affinity of the electron transport layer, and is smaller than the electron affinity of the first light-emitting layer.

A light-emitting device according to a twentieth aspect of the disclosure is the light-emitting device according to any one of the fifteenth to eighteenth aspects, wherein preferably, the first lower layer electrode is a cathode, the first upper layer electrode is an anode, the first light-emitting element further includes an electron transport layer between the first lower layer electrode and the photosensitive resin layer, and the electron affinity of the photosensitive resin layer is smaller than the electron affinity of the electron transport layer, and is greater than the electron affinity of the first light-emitting layer.

A light-emitting device according to a twenty-first aspect of the disclosure is the light-emitting device according to any one of the fifteenth to eighteenth aspects, wherein preferably, the first lower layer electrode is an anode, the first upper layer electrode is a cathode, the first light-emitting element further includes a hole transport layer between the first lower layer electrode and the photosensitive resin layer, and the ionization energy of the photosensitive resin layer is greater than the ionization energy of the hole transport layer, and is greater than the ionization energy of the first light-emitting layer.

A light-emitting device according to a twenty-second aspect of the disclosure is the light-emitting device according to any one of the fifteenth to eighteenth aspects, wherein preferably, the first lower layer electrode is an anode, the first upper layer electrode is a cathode, the first light-emitting element further includes a hole transport layer between the first lower layer electrode and the photosensitive resin layer, and the ionization energy of the photosensitive resin layer is greater than the ionization energy of the hole transport layer, and is smaller than the ionization energy of the first light-emitting layer.

A light-emitting device according to a twenty-third aspect of the disclosure is the light-emitting device according to any one of the fifteenth to twenty-second aspects, wherein preferably, only the first light-emitting element includes the photosensitive resin layer.

A light-emitting device according to a twenty-fourth aspect of the disclosure is the light-emitting device according to any one of the fifteenth to twenty-second aspects, wherein preferably, a second light-emitting element is further provided on the substrate, the second light-emitting element including a second lower layer electrode, a second light-emitting layer having a material differing from that of the first light-emitting layer, and a second upper layer electrode layered in this order from the substrate side, and the second light-emitting element is further provided with the photosensitive resin layer between the second lower layer electrode and the second light-emitting layer.

A light-emitting device according to a twenty-fifth aspect of the disclosure is the light-emitting device according to the twenty-fourth aspect, wherein preferably, a third light-emitting element is further provided on the substrate, the third light-emitting element including a third lower layer electrode, a third light-emitting layer having a material differing from those of both the first light-emitting layer and the second light-emitting layer, and a third upper layer electrode layered in this order from the substrate side.

A light-emitting device according to a twenty-sixth aspect of the disclosure is the light-emitting device according to the twenty-fourth aspect, wherein preferably, a third light-emitting element is further provided on the substrate, the third light-emitting element including a third lower layer electrode, a third light-emitting layer having a material differing from those of both the first light-emitting layer and the second light-emitting layer, and a third upper layer electrode layered in this order from the substrate side, and only the first light-emitting element and the second light-emitting element are provided with the photosensitive resin layer.

A light-emitting device according to a twenty-seventh aspect of the disclosure is the light-emitting device according to the twenty-fifth or twenty-sixth aspect, wherein preferably, the first light-emitting element is a red light-emitting element including a red light-emitting layer as the first light-emitting layer, the second light-emitting element is a green light-emitting element including a green light-emitting layer as the second light-emitting layer, and the third light-emitting element is a blue light-emitting element including a blue light-emitting layer as the third light-emitting layer.

A light-emitting device according to a twenty-eighth aspect of the disclosure is the light-emitting device according to the twenty-seventh aspect, wherein preferably, a display region having a plurality of pixels, and a frame region surrounding the display region are further provided, each of the plurality of pixels includes the red light-emitting element, the green light-emitting element, and the blue light-emitting element, and the substrate includes a thin film transistor layer for driving each of the red light-emitting element, the green light-emitting element, and the blue light-emitting element.

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

1. A method of manufacturing a light-emitting device, the manufacturing method comprising:
light-emitting element formation by forming, on a substrate, a first light-emitting element including a first light-emitting layer,
wherein the light-emitting element formation comprises forming the first light-emitting layer by patterning a first layered body obtained by layering, in order from the substrate side, a first reversal resist, a first light-emitting material layer containing a light-emitting material of the first light-emitting layer, and a first positive resist.

2. The method of manufacturing a light-emitting device according to claim 1,
wherein the formation of the first light-emitting layer comprises:
forming a layered body by forming each layer of the first layered body;
exposing the layered body by exposing a portion of the first layered body after the formation of the layered body; and
subsequent to exposure of the layered body, developing by removing the exposed portion of the first layered body through removal of the exposed first reversal resist.

3. The method of manufacturing a light-emitting device according to claim 1,
wherein the light-emitting element formation further comprises, after the formation of the first light-emitting layer, first re-insolubilization by solubilizing and insolubilizing the first reversal resist overlapping the first light-emitting layer.

4. The method of manufacturing a light-emitting device according to claim 3,
wherein the first re-insolubilization comprises:
exposing the first reversal resist; and
after exposing the first reversal resist, heating the exposed first reversal resist.

5. The method of manufacturing a light-emitting device according to claim 3,
wherein in the light-emitting element formation, a second light-emitting element including a second light-emitting layer including a material differing from that of the first light-emitting layer is further formed on the substrate, and
the light-emitting element formation further comprises, after the first re-insolubilization, forming the second light-emitting layer by patterning a second layered body obtained by layering, in order from the substrate side, a second reversal resist, a second light-emitting material layer containing a light-emitting material of the second light-emitting layer, and a second positive resist.

6. The method of manufacturing a light-emitting device according to claim 5,
wherein the light-emitting element formation further comprises, after the formation of the second light-emitting layer, second re-insolubilization by solubilizing and insolubilizing the second reversal resist overlapping the second light-emitting layer.

7. The method of manufacturing a light-emitting device according to claim 6,
wherein the light-emitting element formation further comprises, after the second re-insolubilization, removing the first positive resist and the second positive resist from an upper layer of the first light-emitting layer and an upper layer of the second light-emitting layer, respectively.

8. The method of manufacturing a light-emitting device according to claim 6,
wherein in the light-emitting element formation, a third light-emitting element including a third light-emitting layer including a material differing from those of both the first light-emitting layer and the second light-emitting layer is further formed on the substrate, and
the light-emitting element formation further comprises, after the second re-insolubilization, forming the third light-emitting layer by patterning a third layered body obtained by layering, in order from the substrate side, a third light-emitting material layer containing a light-emitting material of the third light-emitting layer, and a third positive resist.

9. The method of manufacturing a light-emitting device according to claim 6,
wherein in the light-emitting element formation, a third light-emitting element containing a third light-emitting layer comprising a material differing from those of both the first light-emitting layer and the second light-emitting layer is further formed, and
the light-emitting element formation further comprises, after the second re-insolubilization, forming the third light-emitting layer by patterning a third layered body obtained by layering, in order from the substrate side, a third reversal resist, a third light-emitting material layer containing a light-emitting material of the third light-emitting layer, and a third positive resist.

10. (canceled)

11. (canceled)

12. The method of manufacturing a light-emitting device according to claim 6,
wherein in the light-emitting element formation, a third light-emitting element including a third light-emitting layer including a material differing from those of both the first light-emitting layer and the second light-emitting layer is further formed on the substrate, and
the light-emitting element formation further comprises, after the second re-insolubilization, forming the third light-emitting layer by patterning a third layered body obtained by layering, between two layers of a third positive resist, a third light-emitting material layer containing a light-emitting material of the third light-emitting layer.

13. The method of manufacturing a light-emitting device according to claim 6,
wherein in the light-emitting element formation, a third light-emitting element including a third light-emitting layer including a material differing from those of both the first light-emitting layer and the second light-emitting layer is further formed on the substrate, and
the light-emitting element formation further comprises forming the third light-emitting layer by patterning a third layered body obtained by layering, between two layers of a negative resist, a third light-emitting material layer containing a light-emitting material of the third light-emitting layer.

14. The method of manufacturing a light-emitting device according to claim 1,
wherein the first light-emitting element further comprises a lower layer electrode between the substrate and the first light-emitting layer, and a carrier transport layer between the lower layer electrode and the first light-emitting layer,
the first layered body further comprises, layered between the first reversal resist and the first light-emitting material layer, a carrier transport material layer containing a material of the carrier transport layer, and
in the formation of the first light-emitting layer, the carrier transport material layer is further patterned to form the carrier transport layer.

15. A light-emitting device comprising:
a substrate; and
a first light-emitting element on the substrate, the first light-emitting element including a first lower layer electrode, a first light-emitting layer, and a first upper layer electrode layered in this order from the substrate side,
wherein the first light-emitting element further comprises a photosensitive resin layer between the first lower layer electrode and the first light-emitting layer, and
the photosensitive resin layer includes at least one selected from the group consisting of compounds represented by the structural formulas (1) to (3): 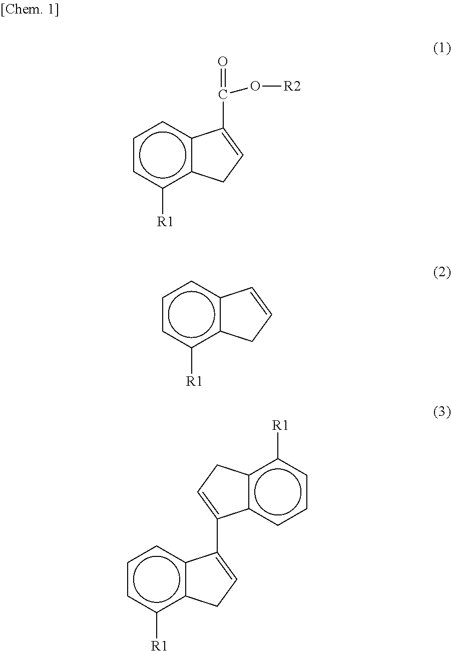
wherein, R1 and R2 each independently represent a substituted or unsubstituted hydrocarbon group.

16. The light-emitting device according to claim 15,
wherein the photosensitive resin layer further comprises at least one selected from the group consisting of aromatic hydrocarbons including a hydroxyl group, 1-hydroxyethyl-2-alkylimidazoline, and shellac.

17. (canceled)

18. (canceled)

19. The light-emitting device according to claim 15,
wherein the first lower layer electrode is a cathode, and the first upper layer electrode is an anode,
the first light-emitting element further comprises an electron transport layer between the first lower layer electrode and the photosensitive resin layer, and
an electron affinity of the photosensitive resin layer is smaller than an electron affinity of the electron transport layer, and is smaller than an electron affinity of the first light-emitting layer.

20. The light-emitting device according to claim 15,
wherein the first lower layer electrode is a cathode, and the first upper layer electrode is an anode,
the first light-emitting element further comprises an electron transport layer between the first lower layer electrode and the photosensitive resin layer, and
an electron affinity of the photosensitive resin layer is smaller than an electron affinity of the electron transport layer, and is greater than an electron affinity of the first light-emitting layer.

21. The light-emitting device according to claim 15,
wherein the first lower layer electrode is an anode, and the first upper layer electrode is a cathode,
the first light-emitting element further comprises a hole transport layer between the first lower layer electrode and the photosensitive resin layer, and
an ionization energy of the photosensitive resin layer is greater than an ionization energy of the hole transport layer, and is greater than an ionization energy of the first light-emitting layer.

22. The light-emitting device according to claim 15,
wherein the first lower layer electrode is an anode, and the first upper layer electrode is a cathode,
the first light-emitting element further comprises a hole transport layer between the first lower layer electrode and the photosensitive resin layer, and
an ionization energy of the photosensitive resin layer is greater than an ionization energy of the hole transport layer, and is smaller than an ionization energy of the first light-emitting layer.

23. The light-emitting device according to claim 15,
wherein only the first light-emitting element comprises the photosensitive resin layer.

24. The light-emitting device according to claim 15,
further comprising a second light-emitting element on the substrate, the second light-emitting element including a second lower layer electrode, a second light-emitting layer including a material differing from that of the first light-emitting layer, and a second upper layer electrode layered in this order from the substrate side,
wherein the second light-emitting element further comprises the photosensitive resin layer between the second lower layer electrode and the second light-emitting layer.

25-28. (canceled)
